(19) United States
(12) Patent Application Publication
(10) Pub. No.: US 2026/0239939 A1
(43) Pub. Date: Aug. 13, 2026

(54) METHOD FOR MANUFACTURING SEMICONDUCTOR DEVICE INCLUDING SEAM-FREE ISOLATION STRUCTURE

(71) Applicant: TAIWAN SEMICONDUCTOR MANUFACTURING COMPANY, LTD., Hsinchu (TW)

(72) Inventors: Po-Hsien CHENG, Hsinchu (TW); Keng-Chu LIN, Hsinchu (TW); Chien-Hung LIN, Hsinchu (TW)

(73) Assignee: TAIWAN SEMICONDUCTOR MANUFACTURING COMPANY, LTD., Hsinchu (TW)

(21) Appl. No.: 19/051,497

(22) Filed: Feb. 12, 2025

(51) Int. Cl. H01L 21/762; H01L 21/3115

(52) U.S. Cl. CPC H10W 10/17; H10P 30/40; H10W 10/0148

(57) ABSTRACT

A method for manufacturing a semiconductor device includes: forming a base semiconductor structure on a substrate; patterning the base semiconductor structure to form a trench that is recessed into the base semiconductor structure along a vertical direction normal to the base semiconductor structure; and performing a cyclic ion implantation process to form an isolation layer portion that fully fills the trench.

### BACKGROUND

With continuous development of semiconductor technology, functionality and electrical performance of a semiconductor device including various semiconductor structures (e.g., transistors, etc.) are being continuously improved. The transistors (e.g., nanosheet transistors, forksheet transistors, etc.) have wide applications due to superior electrical performance. However, improvement in the functionality and electrical performance of the semiconductor device may be hindered by some issues, such as leakage, which may be caused by defects (e.g., seams) formed in an isolation structure of the semiconductor device which is used for isolation and insulation purposes. The semiconductor industry is devoted to solving these issues.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor device in accordance with some embodiments.

FIGS. 2A to 8C are schematic views illustrating some intermediate stages of the method as depicted in FIG. 1 in accordance with some embodiments.

FIGS. 9A and 9B are schematic views illustrating a semiconductor device in accordance with some embodiments.

FIG. 10 is a flow diagram illustrating a method for manufacturing the semiconductor device as depicted in FIGS. 9A and 9B in accordance with some embodiments.

FIGS. 11 to 14B are schematic views illustrating some intermediate stages of the method as depicted in FIG. 10 in accordance with some embodiments.

FIGS. 15A to 15C are schematic views illustrating a semiconductor device in accordance with some embodiments.

FIG. 16 is a flow diagram illustrating a method for manufacturing the semiconductor device as depicted in FIGS. 15A to 15C in accordance with some embodiments.

FIGS. 17 to 19C are schematic views illustrating some intermediate stages of the method as depicted in FIG. 16 in accordance with some embodiments.

FIGS. 20A to 20C are schematic views illustrating a semiconductor device in accordance with some embodiments.

FIG. 21 is a flow diagram illustrating a method for manufacturing the semiconductor device as depicted in FIGS. 20A to 20C in accordance with some embodiments.

FIGS. 22A to 26B are schematic views illustrating some intermediate stages of the method as depicted in FIG. 21 in accordance with some embodiments.

FIG. 27 is a schematic view illustrating a semiconductor device in accordance with some embodiments.

FIG. 28 is a flow diagram illustrating a method for manufacturing the semiconductor device as depicted in FIG. 27 in accordance with some embodiments.

FIGS. 29 to 38 are schematic views illustrating some intermediate stages of the method as depicted in FIG. 28 in accordance with some embodiments.

FIG. 39 is a schematic view illustrating a semiconductor device in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “lower,” “uppermost,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain portion(s)” may refer to a source or a drain, individually or collectively dependent upon the context.

A semiconductor device including a plurality of various semiconductor structures (for example, but not limited to, transistors such as nanosheet field-effect transistor (FET) structures, etc.) has wide applications due to superior device performance. A nanosheet FET structure is a type of a gate-all-around FET (GAAFET) structure. A semiconductor device including nanosheet FET structures may include a semiconductor substrate, a plurality of source/drain regions disposed on the semiconductor substrate, a plurality of isolation structures disposed on the semiconductor substrate, and other elements. Each of the isolation structures, which is used for isolation and insulation purposes of the semiconductor device, usually includes a dielectric material (e.g., silicon nitride or silicon oxide). Formation of the isolation structure involves filling a dielectric material in a hole (e.g., a nano-sized hole) by a flowable chemical vapor deposition (FCVD) process or an atomic layer deposition (ALD) process.

There are advantages and disadvantages of each of the FCVD process and the ALD process which is performed to form an isolation structure.

With regard to the FCVD process, the advantages of the FCVD process include that the isolation structure formed by the FCVD process may have a good quality and less defects (for example, without formation of seams). On the contrary, the disadvantages of the FCVD process include that the isolation structure formed by the FCVD process may have an uncontrollable bottom growth profile such that subsequent processes (for example, etching processes) may not be easily controlled, and that the FCVD process is a high thermal budget process which requires a temperature of greater than about 600° C.

Regarding the ALD process, the advantages of the ALD process include that the ALD process is a low thermal budget process which is performed at a relatively low temperature (for example, a temperature of greater than about 200° C. for formation of the isolation structure made of silicon nitride or a temperature of greater than about 100° C. for formation of the isolation structure made of silicon oxide). However, the isolation structure formed by the ALD process may have a low density region or defects (e.g., seams or voids), which may be induced by van der Waals repulsion. The low density region or the defects in the isolation structure may result in some issues (e.g., a decrease in uniformity of the isolation structure or leakage) after a subsequent etching process.

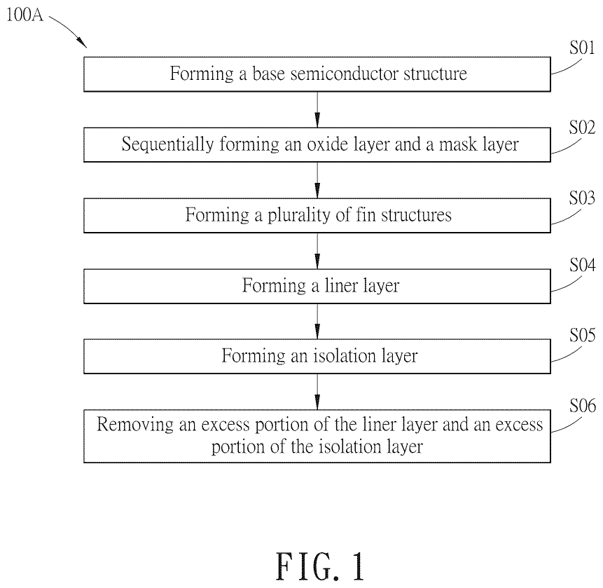

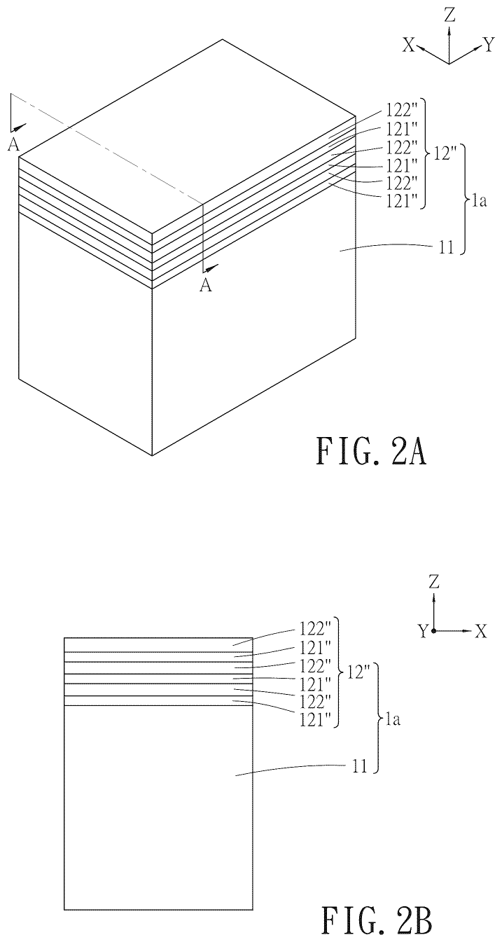

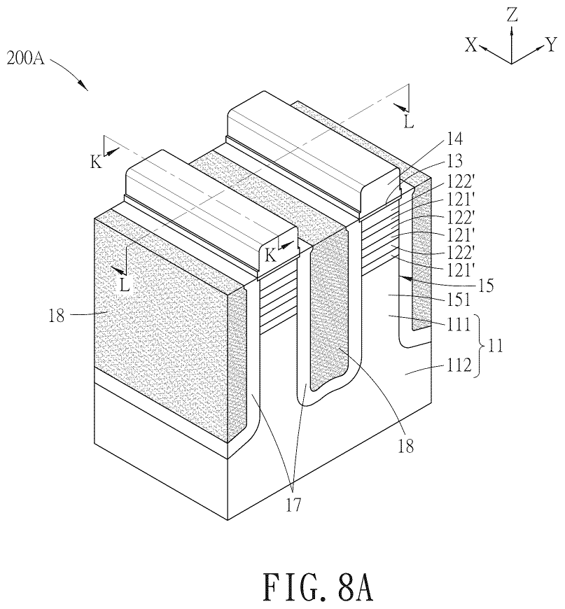

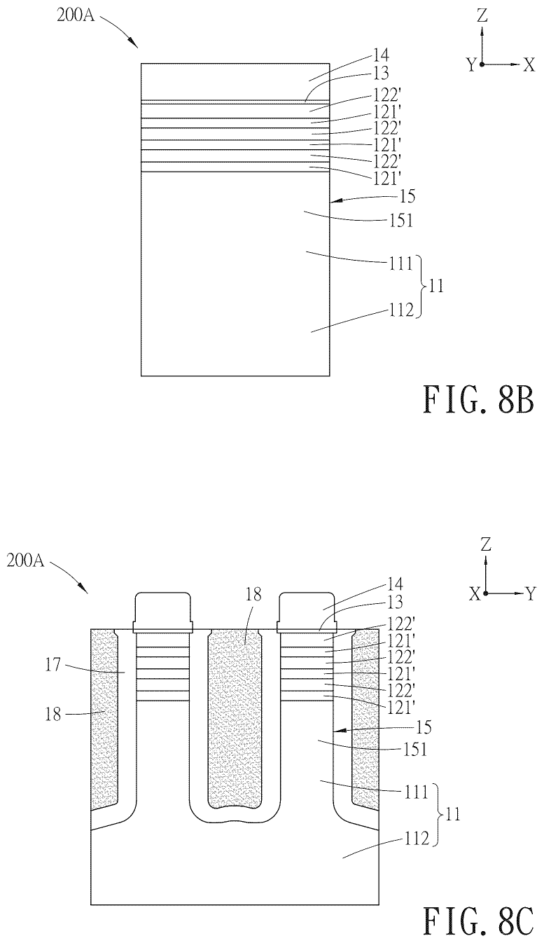

The present disclosure is directed to a semiconductor device and a method for manufacturing the same. FIG. 1 is a flow diagram illustrating a method 100A for manufacturing a semiconductor device 200A shown in FIG. 8A to 8C in accordance with some embodiments. FIGS. 2A to 7C illustrate schematic views of some intermediate stages of the method 100A. Some portions of the semiconductor device 200A may be omitted in FIGS. 2A to 7C for the sake of brevity. Additional steps can be provided before, after or during the method 100A, and some of the steps described herein may be replaced by other steps or be eliminated.

Referring to FIG. 1 and the example illustrated in FIGS. 2A and 2B, the method 100A begins at step S01, where a base semiconductor structure 1a is formed. FIG. 2B illustrates a cross-sectional view taken along line A-A of FIG. 2A. The base semiconductor structure 1a includes a semiconductor substrate 11 and a nanosheet stack 12″.

The semiconductor substrate 11 may include, for example, but not limited to, an elemental semiconductor or a compound semiconductor. In some embodiments, the elemental semiconductor includes a single species of atoms, such as silicon or germanium in column XIV of the periodic table, and may be in a crystal form, a polycrystalline form, or an amorphous form. Other suitable elemental semiconductor materials are within the contemplated scope of the present disclosure. In some embodiments, the compound semiconductor includes two or more elements, and examples thereof may include, silicon carbide, gallium arsenide, gallium phosphide, indium phosphide, indium arsenide, indium antimonide, silicon germanium, gallium arsenide phosphide, aluminum indium arsenide, aluminum gallium arsenide, gallium indium arsenide, gallium indium phosphide, and gallium indium arsenide phosphide. Other suitable compound semiconductor materials are within the contemplated scope of the present disclosure. The compound semiconductor may have a gradient feature in which the compositional ratio thereof changes from one location to another location therein. The compound semiconductor may be formed over a silicon substrate. The compound semiconductor may be strained. In some embodiments, the semiconductor substrate 11 may include a multilayer compound semiconductor structure. In some embodiments, the semiconductor substrate 11 may be a semiconductor on insulator (SOI) (e.g., silicon germanium on insulator (SGOI)). The SOI substrate may be doped with a p-type dopant, for example, but not limited to, boron, aluminum, or gallium. Other suitable p-type dopant materials are within the contemplated scope of the present disclosure. Alternatively, the SOI substrate may be doped with an n-type dopant, for example, but not limited to, nitrogen, phosphorous, or arsenic. Other suitable n-type dopant materials are within the contemplated scope of the present disclosure.

The nanosheet stack 12″ is disposed on the semiconductor substrate 11 in a Z direction normal to the semiconductor substrate 11. The nanosheet stack 12″ includes a plurality of sacrificial layers 121″ and a plurality of channel layers 122″ disposed to alternate with the sacrificial layers 121″ in the Z direction. In some embodiments, the nanosheet stack 12″ is a stack of semiconductor materials. In some embodiments, the sacrificial layers 121″ are made of a first semiconductor material, and the channel layers 122″ are made of a second semiconductor material that is different from the first semiconductor material, so that each layer of the channel layers 122″ has an etching selectivity (or an etching rate) different from that of each layer of the sacrificial layers 121″. In some embodiments, the first semiconductor material may be silicon germanium, and the second semiconductor material may be silicon, so that each layer of the sacrificial layers 121″ has an etching selectivity (or an etching rate) greater than that of each layer of the channel layers 122″. In some embodiments, the nanosheet stack 12″ may be formed on the semiconductor substrate 11 by a suitable deposition process (for example, but not limited to, CVD, ALD, etc.), or a suitable epitaxial growth process (for example, but not limited to, molecular beam epitaxy (MBE), the SEG process, etc.). Other suitable processes for forming the nanosheet stack 12″ are within the contemplated scope of the present disclosure.

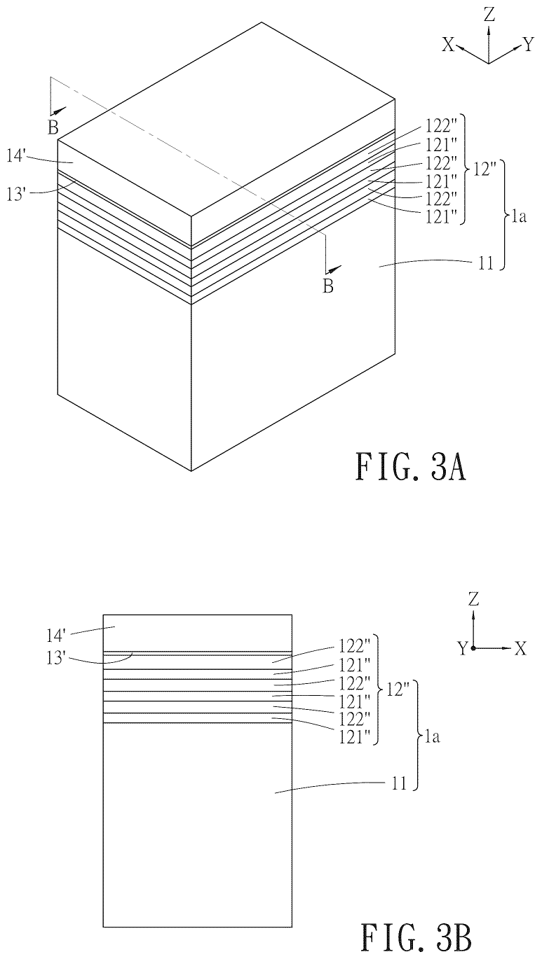

Referring to FIG. 1 and the example illustrated in FIGS. 3A and 3B, the method 100A then proceeds to step S02, where an oxide layer 13′ and a mask layer 14′ are sequentially formed on the base semiconductor structure 1a. FIG. 3B illustrates a cross-sectional view taken along line B-B of FIG. 3A. In some embodiments, the oxide layer 13′ may include, for example, but not limited to, silicon oxide. Other suitable materials for forming the oxide layer 13′ are within the contemplated scope of the present disclosure. In some embodiments, the oxide layer 13′ may be formed by a suitable deposition process, for example, but not limited to, CVD or ALD. Other suitable deposition processes for forming the oxide layer 13′ are within the contemplated scope of the present disclosure. In some embodiments, the mask layer 14′ may be made of a nitride-based material, which may include, for example, but not limited to, silicon nitride or silicon carbonitride. Other suitable materials for forming the mask layer 14′ are within the contemplated scope of the present disclosure. In some embodiments, the mask layer 14′ may be formed by a suitable deposition process, for example, but not limited to, CVD or ALD. Other suitable deposition processes for forming the mask layer 14′ are within the contemplated scope of the present disclosure.

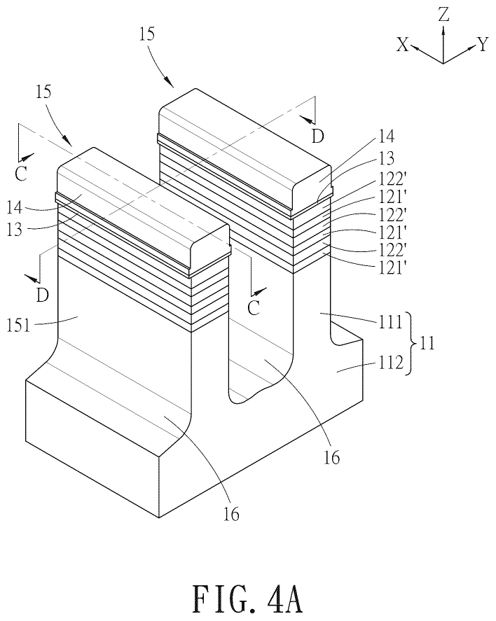

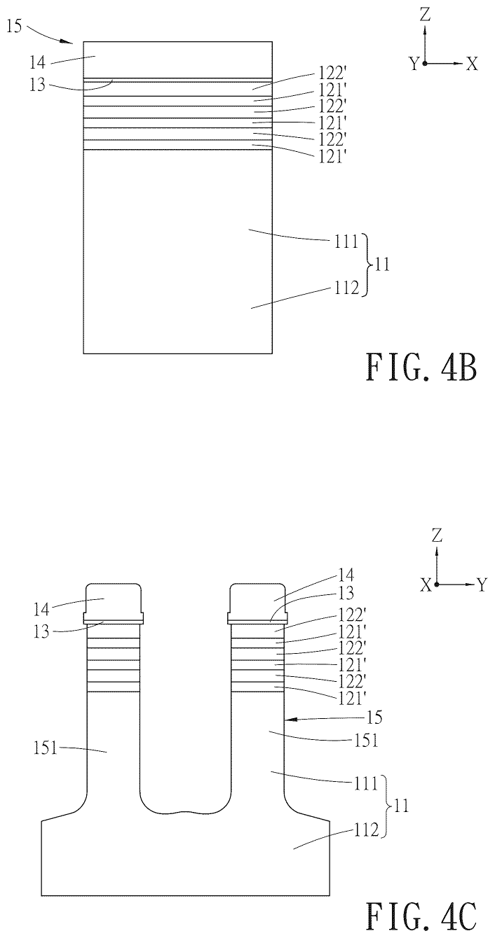

Referring to FIG. 1 and the example illustrated in FIGS. 4A to 4C, the method 100A then proceeds to step S03, where the base semiconductor structure 1a is patterned to form a plurality of fin structures 15. FIG. 4B illustrates a cross-sectional view taken along line C-C of FIG. 4A. FIG. 4C illustrates a cross-sectional view taken along line D-D of FIG. 4A. Step S03 may be performed by a photolithography process, which includes an etching process. The etching process may be, for example, but not limited to, an anisotropic etching process. A plurality of trenches 16 are formed to penetrate the mask layer 14′, the oxide layer 13′, the nanosheet stack 12″ and an upper portion 111 of the semiconductor substrate 11, and terminate at a lower portion 112 of the semiconductor substrate 11. After this step, the sacrificial layers 121″ are formed into a plurality of sacrificial layer portions 121′, the channel layers 122″ are formed into a plurality of channel layer portions 122′, the oxide layer 13′ is formed into a plurality of oxide layer portions 13, and the mask layer 14′ is formed into a plurality of mask layer portions 14. The fin structures 15 extend in an X direction and are spaced apart from each other by the trenches 16 in a Y direction. The X direction is transverse to the Z direction and parallel to the semiconductor substrate 11, and the Y direction is transverse to the X direction and the Z direction. In some embodiments, the X, Y, and Z directions are perpendicular to one another. Each of the fin structures 15 includes a fin portion 151 (formed from the upper portion 111 of the semiconductor substrate 11) disposed on the lower portion 112 of the semiconductor substrate 11, corresponding ones of the sacrificial layer portions 121′, corresponding ones of the channel layer portions 122′ disposed to alternate with the corresponding ones of the sacrificial layer portions 121′ in the Z direction, a corresponding one of the oxide layer portions 13, and a corresponding one of the mask layer portions 14.

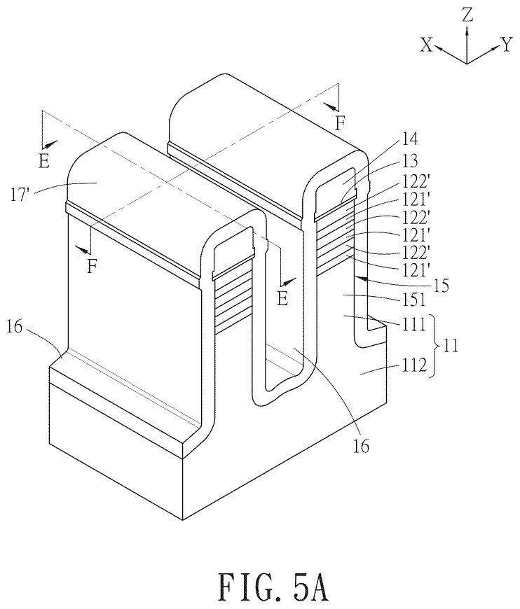

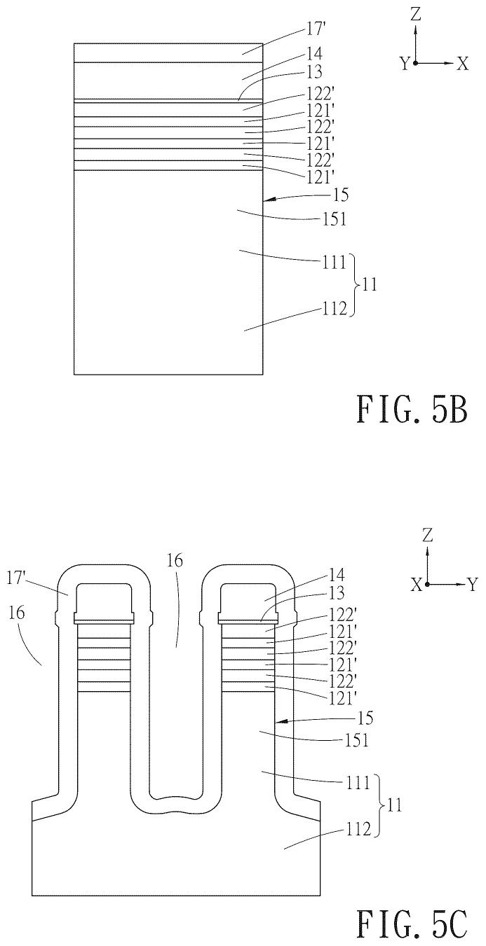

Referring to FIG. 1 and the example illustrated in FIGS. 5A to 5C, the method 100A then proceeds to step S04, where a liner layer 17′ is conformally formed on the structure shown in FIGS. 4A to 4C. FIG. 5B illustrates a cross-sectional view taken along line E-E of FIG. 5A. FIG. 5C illustrates a cross-sectional view taken along line F-F of FIG. 5A. In some embodiments, the liner layer 17′ may include, for example, but not limited to, an oxide-based material (e.g., silicon oxide), a nitride-based material (e.g., silicon nitride), silicon, or combinations thereof. Other suitable materials for forming the liner layer 17′ are within the contemplated scope of the present disclosure. In some embodiments, the liner layer 17′ may be formed by a suitable deposition process, for example, but not limited to, ALD. Other suitable deposition processes for forming the liner layer 17′ are within the contemplated scope of the present disclosure.

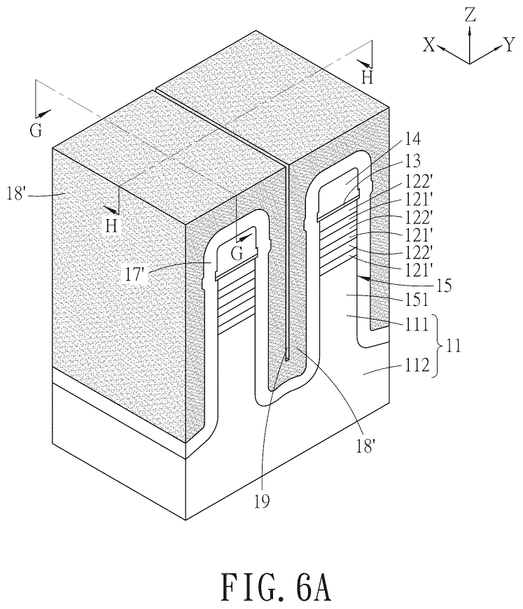

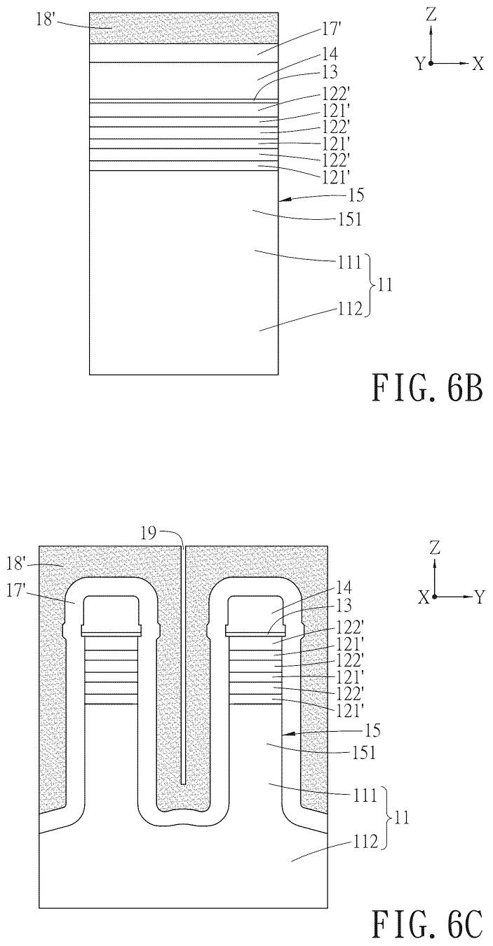

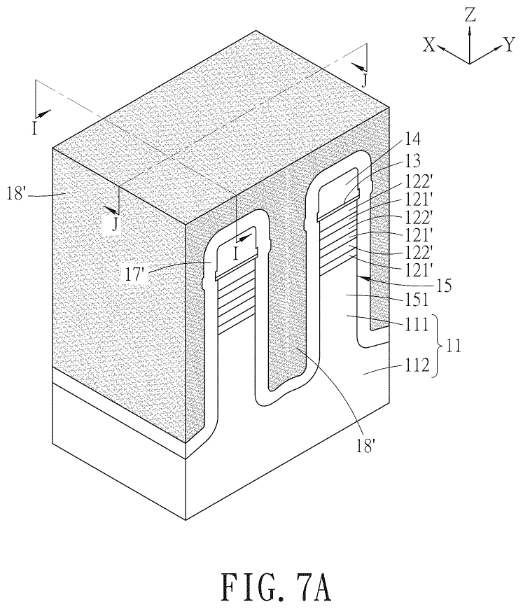

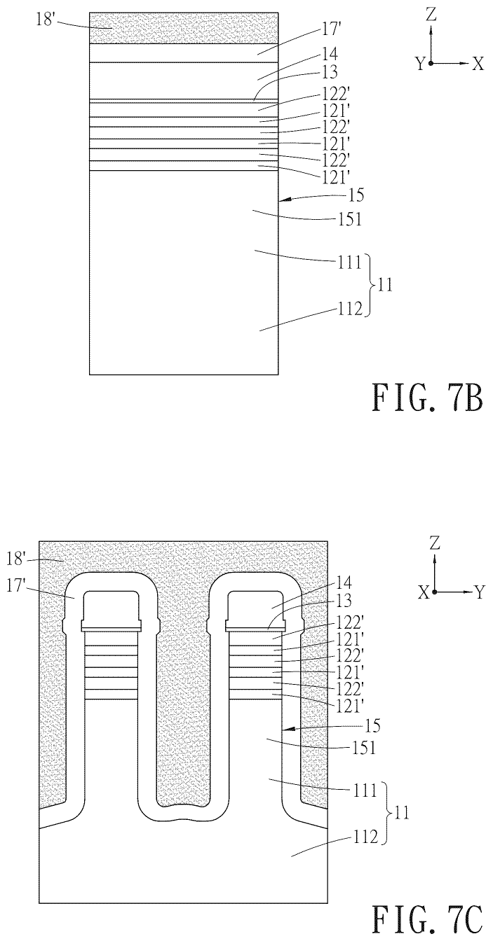

Referring to FIG. 1 and the example illustrated in FIGS. 6A to 7C, the method 100A then proceeds to step S05, where an isolation layer 18′ is formed on the structure shown in FIGS. 5A to 5C. FIG. 6B illustrates a cross-sectional view taken along line G-G of FIG. 6A. FIG. 6C illustrates a cross-sectional view taken along line H-H of FIG. 6A. FIG. 7B illustrates a cross-sectional view taken along line I-I of FIG. 7A. FIG. 7C illustrates a cross-sectional view taken along line J-J of FIG. 7A. In some embodiments, the isolation layer 18′ may include a dielectric material, for example, but not limited to, silicon oxide, silicon nitride, silicon oxynitride, or combinations thereof. Other suitable materials for forming the isolation layer 18′ are within the contemplated scope of the present disclosure. In some embodiments, the isolation layer 18′ and the liner layer 17′ may be made of the same material. In step S05, formation of the isolation layer 18′ may include sub-steps (i) and (ii) described hereinafter.

In sub-step (i), a suitable deposition process, for example, but not limited to, ALD (e.g., plasma-enhanced ALD or thermal ALD) or CVD is performed. In some embodiments, a precursor used for performing the deposition process may include silyl halide represented by a formula of Si(R₁)ₓ(R₂)₄₋ₓ, wherein each R₁ is independently hydrogen, methyl, ethyl, or propyl, each R₂ is independently fluoro, chloro, bromo, or iodo, and x is an integer ranging from 1 to 3. In some embodiments in which the isolation layer 18′ includes or is made of silicon nitride, a reaction gas used to react with the precursor in the deposition process to form the isolation layer 18′ may include a nitrogen-containing gas, for example, but not limited to, nitrogen gas, ammonia gas, hydrazine gas, or combinations thereof. Other suitable nitrogen-containing gases used to react with the precursor in the deposition process are within the contemplated scope of the present disclosure. In some embodiments in which the isolation layer 18′ includes or is made of silicon oxide, a reaction gas used to react with the precursor in the deposition process may include an oxygen-containing gas, for example, but not limited to, oxygen gas, ozone gas, or a combination thereof. Other suitable oxygen-containing gases used to react with the precursor in the deposition process are within the contemplated scope of the present disclosure. In some embodiments in which the isolation layer 18′ includes or is made of silicon oxynitride, a reaction gas used to react with the precursor in the deposition process may include a combination of the nitrogen-containing gas and the oxygen-containing gas.

After the deposition process (for example, ALD), a plurality of defects 19 (e.g., voids or seams) may be formed in the isolation layer 18′ due to the van der Waals repulsion as described above. One of the defects 19 is shown in FIGS. 6A and 6C.

Referring to the example illustrated in FIGS. 7A to 7C, in sub-step (ii), the isolation layer 18′ with the defects 19 (see FIGS. 6A and 6C) is subjected to a cyclic ion implantation process so that the dielectric material fully fills the defects 19. In some embodiments, the cyclic ion implantation process includes one or more cycles of a directional ion implantation process, which includes a first directional ion implantation sub-process and a second directional ion implantation sub-process. In the cyclic ion implantation process, ions produced in each of the first directional ion implantation sub-process and the second directional ion implantation sub-process are implanted into the defects 19 (see FIGS. 6A and 6C) along the Z direction, so that the dielectric material fully fills the defects 19.

In some embodiments, each of the first directional ion implantation sub-process and the second directional ion implantation sub-process may be performed at an implant energy ranging from about 0.5 keV to about 10 keV. If the implant energy is lower than 0.5 keV, the ions produced by each of the first directional ion implantation sub-process and the second directional ion implantation sub-process may not be implanted into the defects 19 along the Z direction. If the implant energy is greater than 10 keV, the fin structures 15 or other elements may be damaged. In some embodiments, each of the first directional ion implantation sub-process and the second directional ion implantation sub-process may be performed at an implant pressure lower than about 1×10⁻⁵ Torr. If the implant pressure is greater than 1×10⁻⁵ Torr, the ions produced by each of the first directional ion implantation sub-process and the second directional ion implantation sub-process may not be implanted into the defects 19 along the Z direction.

In some embodiments in which the isolation layer 18′ includes or is made of silicon nitride, the first directional ion implantation sub-process is performed using a silicon-containing precursor, and the second directional ion implantation sub-process is performed using a nitrogen-containing precursor. In some embodiments, the silicon-containing precursor is the same as or similar to the precursor used in the deposition process described above (i.e., sub-step (i)), and thus details thereof are omitted for the sake of brevity. In some embodiments, the nitrogen-containing precursor is the same as or similar to the nitrogen-containing gas used in the deposition process described above (i.e., sub-step (i)), and thus details thereof are omitted for the sake of brevity. The first directional ion implantation sub-process may be performed before or after the second directional ion implantation sub-process.

In some embodiments in which the isolation layer 18′ includes or is made of silicon oxide, the first directional ion implantation sub-process is performed using the silicon-containing precursor, and the second directional ion implantation sub-process is performed using an oxygen-containing precursor. In some embodiments, the oxygen-containing precursor is the same as or similar to the oxygen-containing gas used in the deposition process described above (i.e., sub-step (i)), and thus details thereof are omitted for the sake of brevity. The first directional ion implantation sub-process may be performed before or after the second directional ion implantation sub-process.

In some embodiments in which the isolation layer 18′ includes or is made of silicon oxynitride, the directional ion implantation process further includes a third directional ion implantation sub-process. In this case, the first directional ion implantation sub-process is performed using the silicon-containing precursor, the second directional ion implantation sub-process is performed using the nitrogen-containing precursor, and the third directional ion implantation sub-process is performed using the oxygen-containing precursor. The first directional ion implantation sub-process, the second directional ion implantation sub-process, and the third directional ion implantation sub-process may be performed in any suitable order.

After this step, the defects 19 (see FIGS. 6A and 6C) in the isolation layer 18′ may be eliminated. In some embodiments, a thickness of the isolation layer 18′ may be increased by about 2 nm to about 8 nm after each of the first directional ion implantation sub-process, the second directional ion implantation sub-process, and the third directional ion implantation sub-process.

By performing the cyclic ion implantation process after the deposition process (for example, ALD), the defects 19 (e.g., voids or seams, see FIGS. 6A and 6C) in the isolation layer 18′ formed after the deposition process can be eliminated.

Referring to FIG. 1 and the example illustrated in FIGS. 8A to 8C, the method 100A then proceeds to step S06, where an excess portion of the liner layer 17′ and an excess portion of the isolation layer 18′ are removed. FIG. 8B illustrates a cross-sectional view taken along line K-K of FIG. 8A. FIG. 8C illustrates a cross-sectional view taken along line L-L of FIG. 8A. Step S06 may be performed by a suitable etching process, for example, but not limited to, a dry etching process, a wet etching process, or a combination thereof. Other suitable etching processes are within the contemplated scope of the present disclosure. After this step, the liner layer 17′ is formed into a plurality of liners 17, and the isolation layer 18′ is formed into a plurality of isolation layer portions 18. The isolation layer portions 18 are formed on the lower portion 112 of the semiconductor substrate 11. Each pair of the isolation layer portions 18 is located at two opposite sides of the fin portion 151 of a corresponding one of the fin structures 15, so as to separate and isolate the fin structures 15 from each other. The two opposite sides of the fin portion 151 of a corresponding one of the fin structures 15 are opposite to each other in the Y direction. In some embodiments, each of the isolation layer portions 18 has a width ranging from about 10 nm to about 400 nm. In some embodiments, each of the isolation layer portions 18 has a thickness ranging from about 60 nm to about 250 nm. In some embodiments, each of the isolation layer portions 18 may be a portion of a shallow trench isolation (STI), a deep trench isolation (DTI), or other suitable isolation structures.

After step S06, the semiconductor device 200A is obtained. In some embodiments, after formation of the liner layer 17′ (i.e., step S04), the structure shown in FIGS. 4A to 4C can be directly subjected to the cyclic ion implantation process so as to form the isolation layer 18′. That is, sub-step (i) (i.e., the deposition process) of step S05 can be omitted.

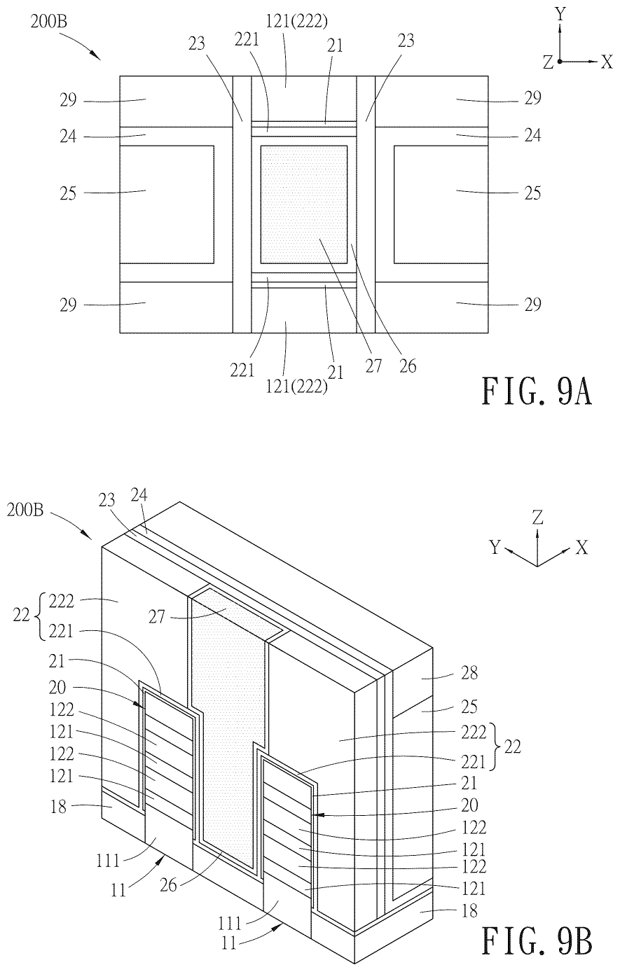

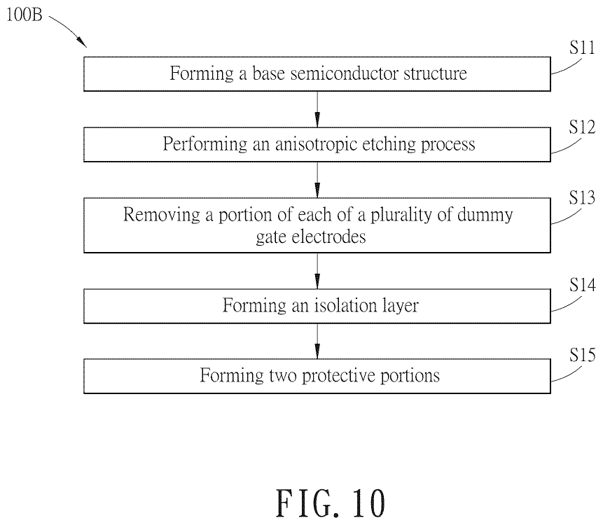

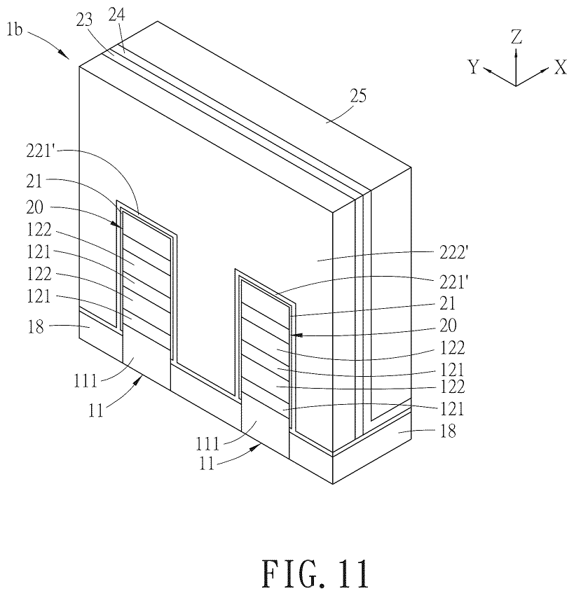

FIGS. 9A and 9B illustrate a semiconductor device 200B in accordance with some embodiments. FIG. 10 is a flow diagram illustrating a method 100B for manufacturing the semiconductor device 200B in accordance with some embodiments. FIGS. 11 to 14B illustrate schematic views of some intermediate stages of the method 100B. Some portions of the semiconductor device 200B may be omitted in FIGS. 11 to 14B for the sake of brevity. Additional steps can be provided before, after or during the method 100B, and some of the steps described herein may be replaced by other steps or be eliminated. In some embodiments, the semiconductor device 200B is formed from the semiconductor device 200A shown in FIGS. 8A to 8C.

As shown in FIGS. 9A and 9B, the semiconductor device 200B includes the semiconductor substrate 11, the isolation layer portions 18, two stack sections 20, two liners 21, two dummy poly gate sections 22, two gate spacers 23, two contact etch stop portions 24, two inter-layer dielectric (ILD) portions 25, a liner 26, an isolation layer 27, two protective portions 28, and a plurality of source/drain portions 29. One of the gate spacers 23, one of the contact etch stop portions 24, one of the ILD portions 25, and one of the protective portions 28 are shown in FIG. 9B.

Each of the stack sections 20 is disposed on the semiconductor substrate 11, and includes a plurality of sacrificial features 121 (formed from the sacrificial layer portions 121′ of the semiconductor device 200A) and a plurality of channel features 122 (formed from the channel layer portions 122′ of the semiconductor device 200A). The sacrificial features 121 and the channel features 122 are alternately stacked in the Z direction.

The liners 21 cover the stack sections 20, respectively. In some embodiments, the liners 21 include or are made of, for example, but not limited to, silicon. Other suitable materials for forming the liners 21 are within the contemplated scope of the present disclosure. In some embodiments, each of the liners 21 is used to prevent oxidation of the sacrificial features 121 and the channel features 122 of a corresponding one of the stack sections 20.

The dummy poly gate sections 22 are disposed on the isolation layer portions 18, respectively. In some embodiments, each of the dummy poly gate sections 22 includes a dummy gate dielectric 221 and a dummy gate electrode 222. In some embodiments, the dummy gate dielectric 221 includes or is made of, for example, but not limited to, an oxide-based material (e.g., silicon oxide). Other suitable materials for forming the dummy gate dielectric 221 are within the contemplated scope of the present disclosure. In some embodiments, the dummy gate electrode 222 may include, for example, but not limited to, polysilicon. Other suitable materials for forming the dummy gate electrode 222 are within the contemplated scope of the present disclosure.

Each of the gate spacers 23 is disposed on the isolation layer portions 18, and at a side of each of the dummy poly gate sections 22. In some embodiments, the gate spacers 23 include or are made of, for example, but not limited to, silicon nitride, silicon carbon nitride, silicon oxycarbonnitride, silicon oxycarbide, or combinations thereof. Other suitable materials for forming the gate spacer 23 are within the contemplated scope of the present disclosure. In some embodiments, each of the gate spacers 23 may be formed as a single layer structure or a multi-layered structure.

Each of the contact etch stop portions 24 is disposed on the isolation layer portions 18 and at a side of a corresponding one of the gate spacers 23 opposite to the dummy poly gate sections 22 in the X direction. In some embodiments, the contact etch stop portions 24 include or are made of, for example, but not limited to, silicon nitride, carbon-doped silicon nitride, or a combination thereof. Other suitable materials for forming the contact etch stop portion 24 are within the contemplated scope of the present disclosure.

Each of the ILD portions 25 is surrounded by a corresponding one of the contact etch stop portions 24. In some embodiments, the ILD portions 25 include or are made of a dielectric material, for example, but not limited to, silicon oxide, silicon nitride, silicon oxynitride, other low-dielectric constant (k) dielectric materials, or combinations thereof. Other suitable materials for forming the ILD portions 25 are within the contemplated scope of the present disclosure.

The liner 26 is disposed between the dummy poly gate sections 22 and on a corresponding one of the isolation layer portions 18. In some embodiments, the liner 26 includes or is made of a dielectric material, for example, but not limited to, silicon oxide, silicon oxycarbide, or a combination thereof. Other suitable materials for forming the liner 26 are within the contemplated scope of the present disclosure.

The isolation layer 27 is covered by the liner 26. In some embodiments, the isolation layer 27 has a width (in the X direction) ranging from about 3 nm to about 20 nm. In some embodiments, the isolation layer 27 has a thickness (in the Z direction) ranging from about 60 nm to about 100 nm.

Each of the protective portions 28 is disposed on a corresponding one of the ILD portions 25, and is laterally covered by a corresponding one of the contact etch stop portions 24. In some embodiments, the protective portions 28 include or are made of, for example, but not limited to, a nitride-based material. Other suitable materials for forming the protective portions 28 are within the contemplated scope of the present disclosure.

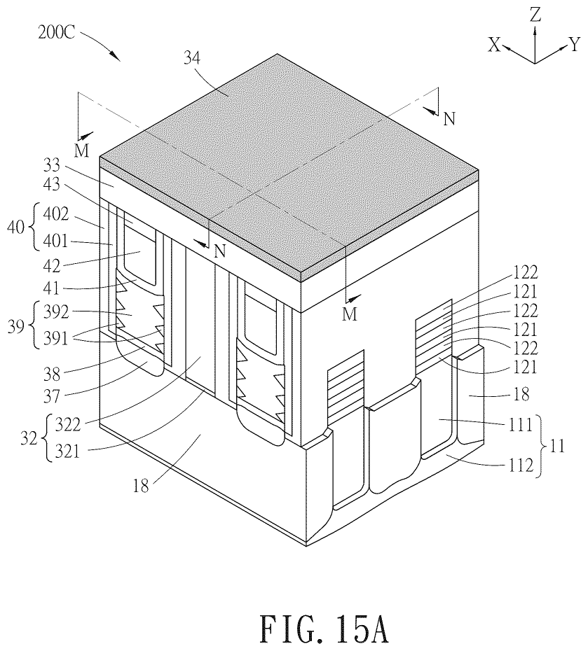

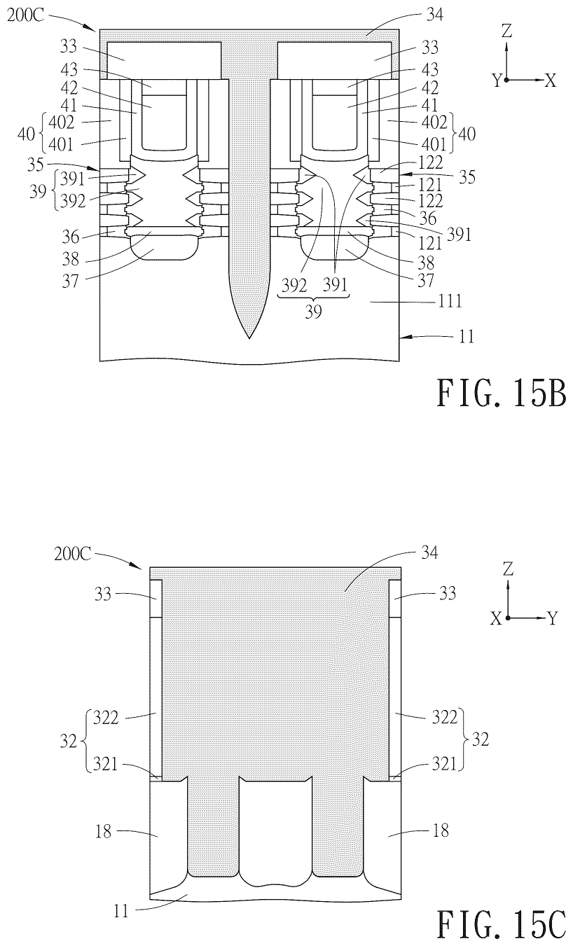

Each pair of the source/drain portions 29 is located at two opposite sides of a corresponding one of the contact etch stop portions 24 in the Y direction. A structure of each of the source/drain portions 29 is similar to or the same as that of a source/drain portion 39 (with reference to FIGS. 15A and 15B).

Referring to FIG. 10 and the example illustrated in FIG. 11, the method 100B begins at step S11, where a base semiconductor structure 1b is formed. The base semiconductor structure 1b includes the semiconductor substrate 11, the isolation layer portions 18, the stack sections 20, the liners 21, a dummy gate dielectric layer 221′, a dummy gate electrode layer 222′, the gate spacers 23, the contact etch stop portions 24, and the ILD portions 25. One of the gate spacers 23, one of the contact etch stop portions 24, and one of the ILD portions 25 are shown in FIG. 11.

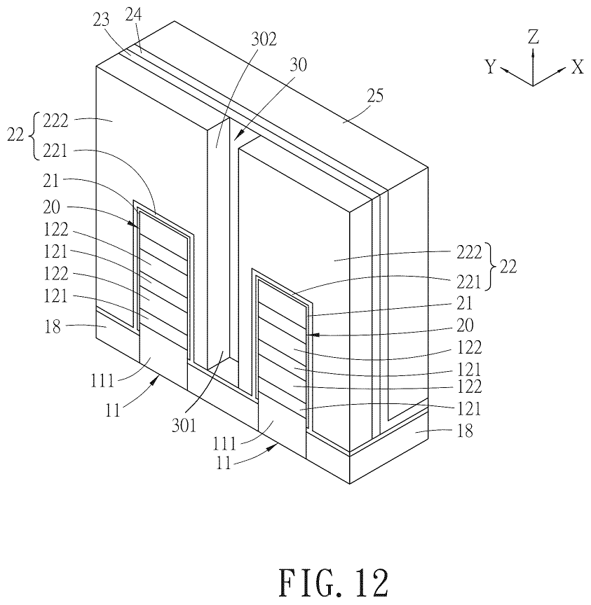

Referring to FIG. 10 and the example illustrated in FIG. 12, the method 100B then proceeds to step S12, where an anisotropic etching process is performed on the base semiconductor structure 1b shown in FIG. 11, so as to form a trench 30. The trench 30 is formed between the stack sections 20, penetrates the dummy gate dielectric layer 221′ and the dummy gate electrode layer 222′, and terminates at an upper surface of a corresponding one of the isolation layer portions 18. After this step, the dummy gate dielectric layer 221′ is formed into the dummy gate dielectrics 221, and the dummy gate electrode layer 222′ is formed into the dummy gate electrodes 222. In some embodiments, the trench 30 is divided into a lower trench portion 301 and an upper trench portion 302 that is located above the lower trench portion 301 and that is in fluid communication with the lower trench portion 301.

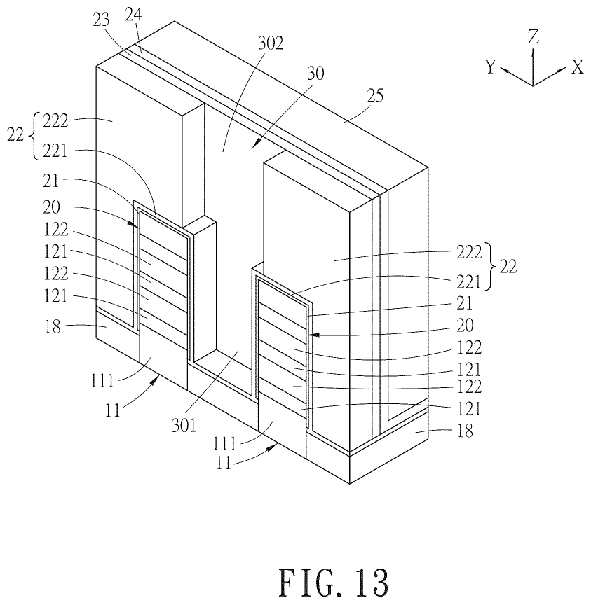

Referring to FIG. 10 and the example illustrated in FIG. 13, the method 100B then proceeds to step S13, where a portion of each of the dummy gate electrodes 222 is removed until a portion of each of the dummy gate dielectrics 221 is exposed. Step S13 is performed by a suitable etching process, for example, but not limited to, a dry etching process, a wet etching process, or a combination thereof. Other suitable etching processes are within the contemplated scope of the present disclosure. After this step, a width (in the Y direction) of each of the lower trench portion 301 and the upper trench portion 302 increases.

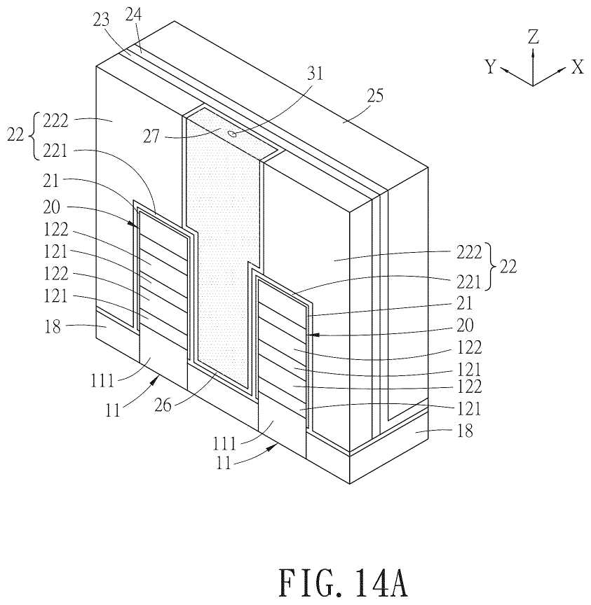

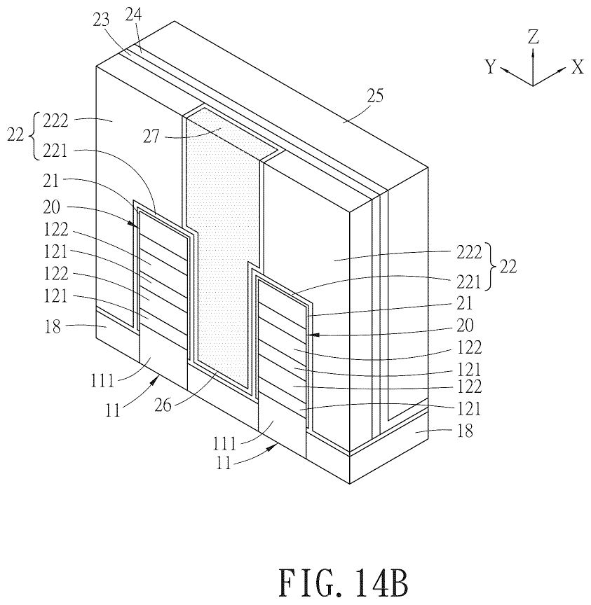

Referring to FIG. 10 and the example illustrated in FIGS. 14A and 14B, the method 100B then proceeds to step S14, where the isolation layer 27 is formed on the structure shown in FIG. 13 so that the isolation layer 27 fully fills the trench 30. Step S14 includes sub-steps (i) and (ii). Sub-step (i) of step S14 is performed by a suitable deposition process. The material and processes for performing the deposition process of sub-step (i) of step S14 are the same as or similar to those for performing the deposition process of sub-step (i) of step S05 (for forming the isolation layer 18′) in the method 100A, and thus details thereof are omitted for the sake of brevity. After the deposition process of sub-step (i) of step S14, a plurality of defects (e.g., voids or seams) 31 may be formed in the isolation layer 27 (see FIG. 14A). One of the defects 31 is shown in FIG. 14A.

Sub-step (ii) of step S14 is performed by a cyclic ion implantation process. The material and processes for performing the cyclic ion implantation process of sub-step (ii) of step S14 are the same as or similar to those for performing the cyclic ion implantation process of sub-step (ii) of step S05 (for forming the isolation layer 18′) in the method 100A, and thus details thereof are omitted for the sake of brevity. It is noted that the defects 31 in the isolation layer 27 of the structure shown in FIG. 14A can be eliminated after sub-step (ii) of step S14 (see FIG. 14B).

Referring to FIG. 10 and the example illustrated in FIG. 9B, the method 100B then proceeds to step S15, where the protective portions 28 are formed. Step S15 includes sub-steps (i) to (iii). In sub-step (i), a portion of each of the ILD portions 25 is removed by a suitable etching process, so as to form a hole (not shown). In sub-step (ii), a protective material layer is formed by a suitable deposition process (for example, but not limited to, CVD), so that the protective material layer fills the hole. In sub-step (iii), an excess portion of the protective material layer is removed, so as to obtain the protective portions 28.

After sub-step (iii) of step S15, the semiconductor device 200B shown in FIGS. 9A and 9B is obtained.

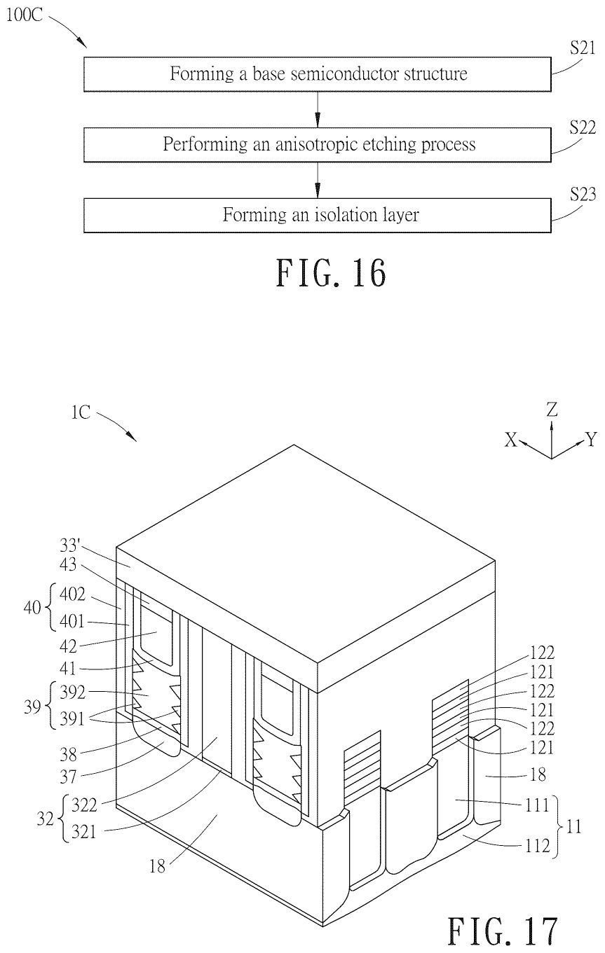

FIGS. 15A to 15C illustrate a semiconductor device 200C in accordance with some embodiments. FIG. 15B illustrates a cross-sectional view taken along line M-M of FIG. 15A. FIG. 15C illustrates a cross-sectional view taken along line N-N of FIG. 15A. FIG. 16 is a flow diagram illustrating a method 100C for manufacturing the semiconductor device 200C in accordance with some embodiments. FIGS. 17 to 19C illustrate schematic views of some intermediate stages of the method 100C. Some portions of the semiconductor device 200C may be omitted in FIGS. 17 to 19C for the sake of brevity. Additional steps can be provided before, after or during the method 100C, and some of the steps described herein may be replaced by other steps or be eliminated. In some embodiments, the semiconductor device 200C may be formed from the semiconductor device 200B shown in FIGS. 9A and 9B.

As shown in FIGS. 15A to 15C, the semiconductor device 200C includes the semiconductor substrate 11, the isolation layer portions 18, a plurality of nanosheet structures, a plurality of dummy poly gates 32, a plurality of mask portions 33, and an isolation layer 34.

Each of the nanosheet structures includes two stack sections 35, a plurality of inner spacers 36, a base layer 37, an insulator 38, the source/drain portion 39, two gate spacers 40, a contact etch stop portion 41, an ILD portion 42, and a protective portion 43.

Each of the stack sections 35 is disposed on the semiconductor substrate 11, and includes the sacrificial features 121 and the channel features 122 alternately stacked in the Z direction. The structure of each of the stack sections 35 is similar to that of each of the stack sections 20 shown in FIG. 9B.

Each of the inner spacers 36 is laterally disposed on a corresponding one of the sacrificial features 121. In some embodiments, each of the inner spacers 36 may include, for example, but not limited to, silicon oxide, silicon nitride, silicon carbide, silicon oxycarbide, silicon oxynitride, silicon carbonitride, silicon oxycarbonitride, low-k materials, or combinations thereof. Other suitable materials for forming the inner spacers 36 are within the contemplated scope of the present disclosure.

The base layer 37 is disposed on the semiconductor substrate 11 and between the stack sections 35. In some embodiments, the base layer 37 includes or is made of, for example, but not limited to, silicon. Other suitable materials for forming the base layer 37 are within the contemplated scope of the present disclosure.

The insulator 38 is disposed on the base layer 37 opposite to the semiconductor substrate 11. In some embodiments, the insulator 38 includes or is made of a dielectric material, for example, but not limited to, silicon nitride, silicon oxide, silicon oxynitride, or combinations thereof. Other suitable materials for forming the insulator 38 are within the contemplated scope of the present disclosure.

The source/drain portion 39 includes a plurality of seed portions 391 and an epitaxial layer 392.

Each of the seed portions 391 is disposed on a side of a corresponding one of the channel features 122. In some embodiments, each of the seed portions 391 includes or is made of, for example, but not limited to, silicon, silicon germanium, silicon boron, silicon phosphide, silicon arsenic, or combinations thereof. Other suitable materials for forming the seed portions 391 are within the contemplated scope of the present disclosure.

The epitaxial layer 392 is disposed over the seed portions 391 and on the insulator 38 opposite to the base layer 37. In some embodiments, the epitaxial layer 392 includes or is made of, for example, but not limited to, silicon, silicon germanium, silicon boron, silicon phosphide, silicon arsenic, or combinations thereof.

The material for forming the gate spacers 40 is the same as or similar to that for forming the gate spacers 23 of the semiconductor device 200B shown in FIG. 9B, and thus details thereof are omitted for the sake of brevity. In some embodiments, when each of the gate spacers 40 is formed as the multi-layered structure (e.g., a two-layered structure), each of the gate spacers 40 may include an outer part 401 and an inner part 402 disposed between a corresponding one of the dummy poly gates 32 and the outer part 401.

The contact etch stop portion 41 is disposed on the source/drain portion 39 opposite to the insulator 38, and between the gate spacers 40. The material for forming the contact etch stop portion 41 is the same as or similar to that for forming the contact etch stop portions 24 of the semiconductor device 200B shown in FIG. 9B, and thus details thereof are omitted for the sake of brevity.

The ILD portion 42 is surrounded by the contact etch stop portion 41. The material for forming the ILD portion 42 is the same as or similar to that for forming the ILD portions 25 of the semiconductor device 200B shown in FIG. 9B, and thus details thereof are omitted for the sake of brevity.

The protective portion 43 is disposed on the ILD portion 42 and is laterally covered by the contact etch stop portion 41. The material for forming the protective portion 43 is the same as or similar to that for forming the protective portion 28 of the semiconductor device 200B shown in FIG. 9B, and thus details thereof are omitted for the sake of brevity.

Each of the dummy poly gates 32 is disposed on the isolation layer portions 18, and between two adjacent ones of the nanosheet structures. Each of the dummy poly gates 32 includes a dummy gate dielectric 321 and a dummy gate electrode 322 disposed on the dummy gate dielectric 321. The material for forming each of the dummy gate dielectric 321 and the dummy gate electrode 322 is the same as or similar to that for forming each of the dummy gate dielectric 221 and the dummy gate electrode 222 of the semiconductor device 200B shown in FIG. 9B, and thus details thereof are omitted for the sake of brevity.

The mask portions 33 are disposed on the nanosheet structures opposite to the semiconductor substrate 11. The mask portions 33 are formed from a mask layer 33′ (with reference to FIG. 17). In some embodiments, the mask layer 33′ may include, for example, but not limited to, silicon nitride, silicon carbonitride, or a combination thereof. Other suitable materials for forming the mask layer 33′ are within the contemplated scope of the present disclosure.

The isolation layer 34 includes a horizontal portion that is disposed on an upper surface of each of the mask portions 33, and a vertical portion that extends downwardly from the horizontal portion and that is disposed between two adjacent ones of the nanosheet structures.

Referring to FIG. 16 and the example illustrated in FIG. 17, the method 100C begins at step S21, where a base semiconductor structure 1c is formed. The base semiconductor structure 1c includes the semiconductor substrate 11, the isolation layer portions 18, the nanosheet structures, the dummy poly gates 32, and the mask layer 33′.

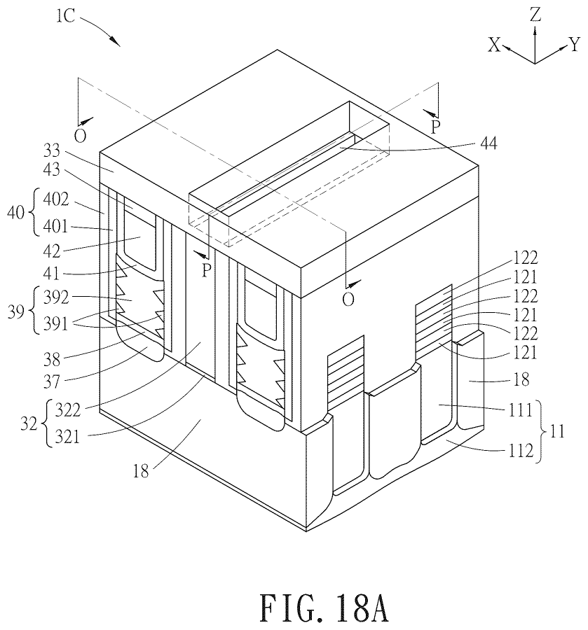

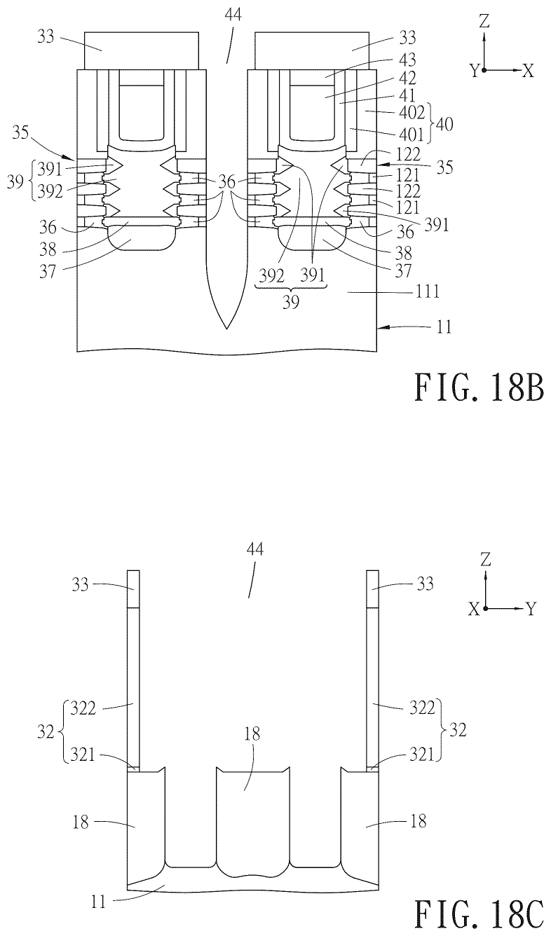

Referring to FIG. 16 and the example illustrated in FIGS. 18A to 18C, the method 100C then proceeds to step S22, where an anisotropic etching process is performed on the base semiconductor structure 1c shown in FIG. 17. FIG. 18B illustrates a cross-sectional view taken along line O-O of FIG. 18A. FIG. 18C illustrates a cross-sectional view taken along line P-P of FIG. 18A. After this step, a portion of the mask layer 33′, a portion of a corresponding one of the dummy poly gates 32, corresponding ones of the sacrificial features 121 and corresponding ones of the channel features 122 are removed, so as to form a trench 44. A remaining portion of the mask layer 33′ is formed into the mask portions 33.

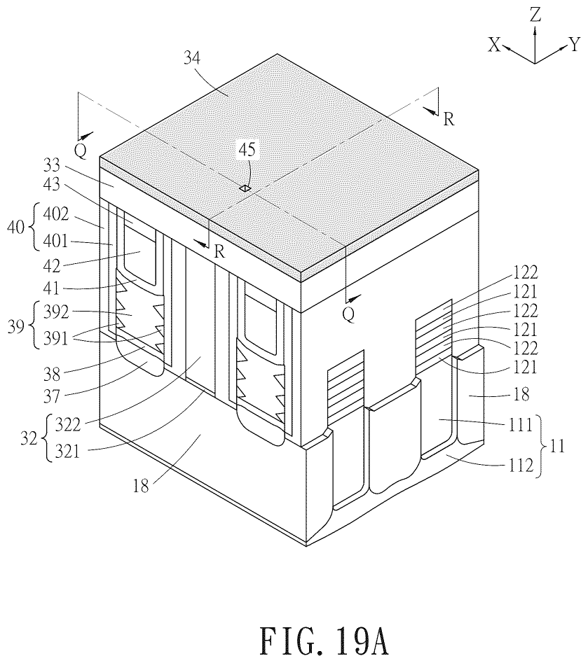

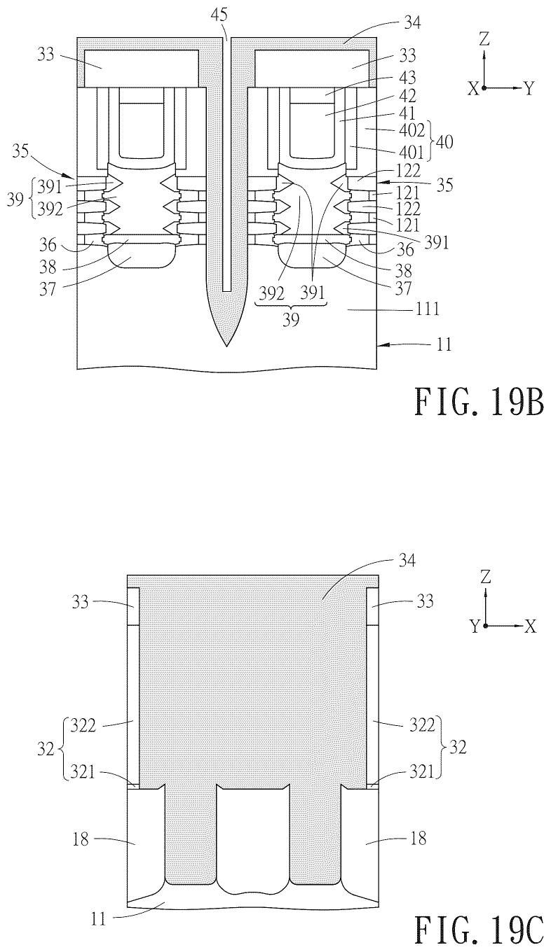

Referring to FIG. 16 and the example illustrated in FIGS. 19A to 19C and FIGS. 15A to 15C, the method 100C then proceeds to step S23, where the isolation layer 34 is formed on the structure shown in FIGS. 18A to 18C so that the isolation layer 34 fully fills the trench 44. FIG. 19B illustrates a cross-sectional view taken along line Q-Q of FIG. 19A. FIG. 19C illustrates a cross-sectional view taken along line R-R of FIG. 19A. Step S23 (i.e., formation of the isolation layer 34) includes sub-steps (i) and (ii). Sub-step (i) of step S23 is performed by a suitable deposition process. The material and processes for performing the deposition process of sub-step (i) of step S23 are the same as or similar to those for performing the deposition process of sub-step (i) of step S05 (for forming the isolation layer 18′) in the method 100A, and thus details thereof are omitted for the sake of brevity. After the deposition process of sub-step (i) of step S23, a plurality of defects (e.g., voids or seams) 45 may be formed in the isolation layer 34.

Sub-step (ii) of step S23 is performed by a cyclic ion implantation process. The material and processes for performing the cyclic ion implantation process of sub-step (ii) of step S23 are the same as or similar to those for performing the cyclic ion implantation process of sub-step (ii) of step S05 (for forming the isolation layer 18′) in the method 100A, and thus details thereof are omitted for the sake of brevity. After sub-step (ii) of step S23, the semiconductor device 200C shown in FIGS. 15A to 15C is obtained. It is noted that the defects 45 formed in the isolation layer 34 of the structure shown in FIG. 19B can be eliminated after sub-step (ii) of step S23.

In some embodiments, after step S23, a suitable planarization process may be performed to remove the horizontal portion of the isolation layer 34. In some embodiments, the vertical portion of the isolation layer 34 may have a width ranging from about 10 nm to about 400 nm (in the X direction) and a thickness ranging from about 60 nm to about 250 nm (in the Z direction). In some embodiments, the planarization process may be a chemical mechanical polishing (CMP) or other suitable planarization processes. In some embodiments, the vertical portion of the isolation layer 34 is referred to as a connected polysilicon-on-oxide-definition (OD) edge (CPODE) structure.

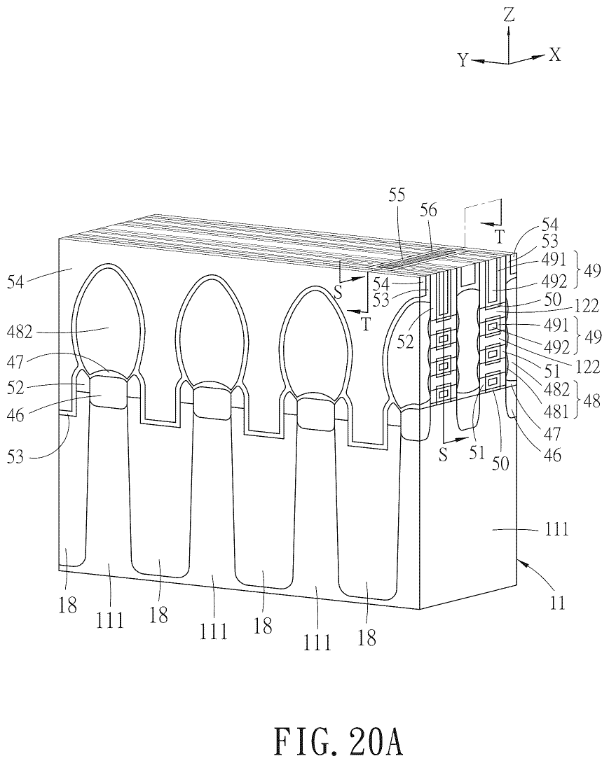

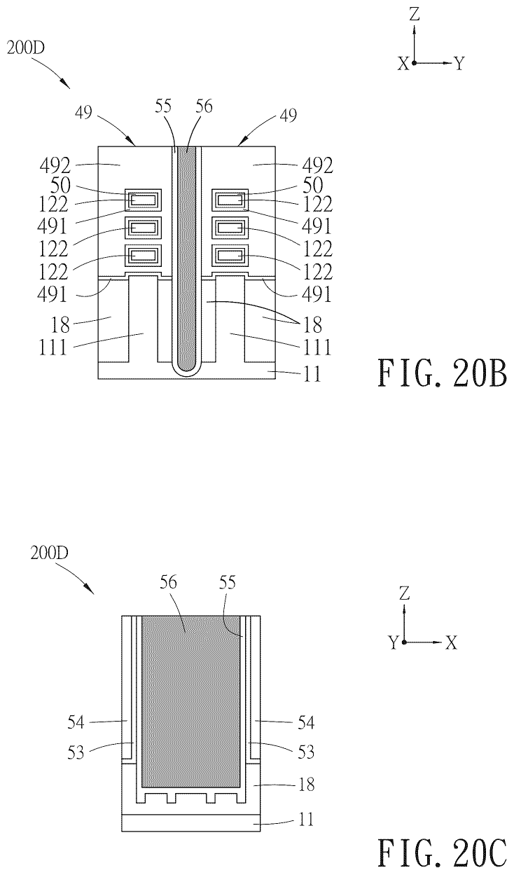

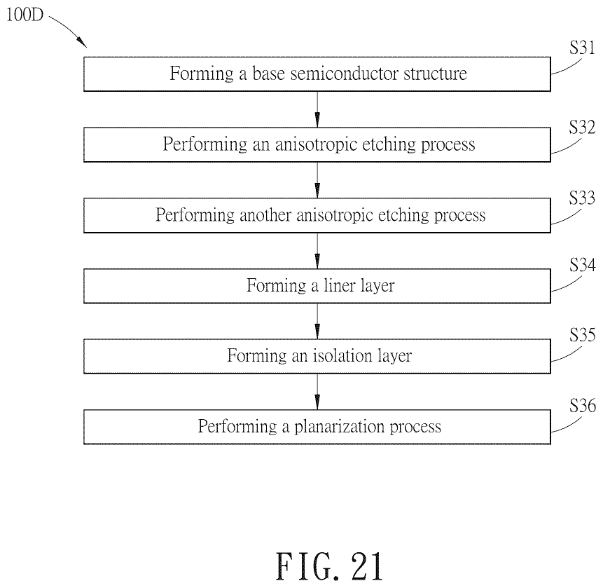

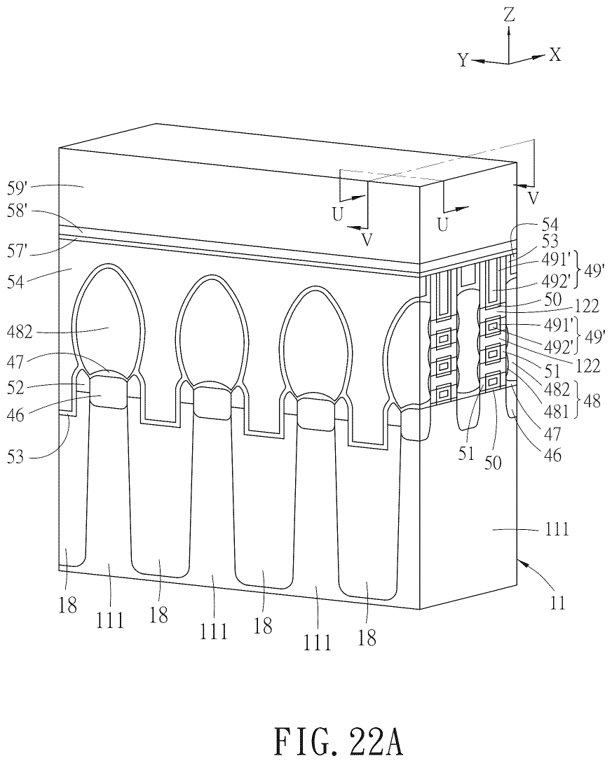

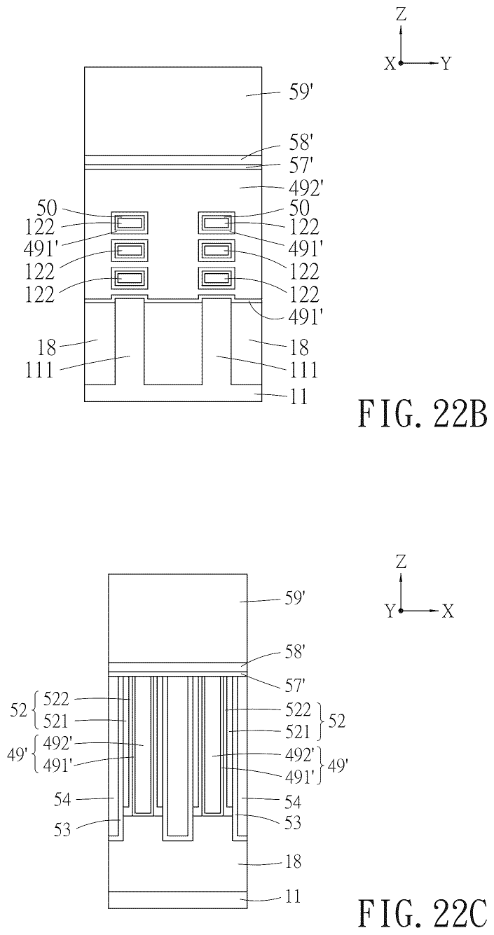

FIGS. 20A to 20C illustrate a semiconductor device 200D in accordance with some embodiments. FIG. 20B illustrates a cross-sectional view taken along line S-S of FIG. 20A. FIG. 20C illustrates a cross-sectional view taken along line T-T of FIG. 20A. FIG. 21 is a flow diagram illustrating a method 100D for manufacturing the semiconductor device 200D in accordance with some embodiments. FIGS. 22A to 26B illustrate schematic views of some intermediate stages of the method 100D. Some portions of the semiconductor device 200D may be omitted in FIGS. 22A to 26B for the sake of brevity. Additional steps can be provided before, after or during the method 100D, and some of the steps described herein may be replaced by other steps or be eliminated. In some embodiments, the semiconductor device 200D may be formed from the semiconductor device 200C shown in FIGS. 15A to 15C.

As shown in FIGS. 20A to 20C, the semiconductor device 200D includes the semiconductor substrate 11, the isolation layer portions 18, a plurality of base layers 46, a plurality of insulators 47, a plurality of source/drain portions 48, a plurality of metal gate portions 49, a plurality of interfacial features 50, a plurality of inner spacers 51, a plurality of gate spacers 52, a plurality of contact etch stop portions 53, a plurality of ILD portions 54, a liner 55, and an isolation layer portion 56.

The base layers 46 are disposed on the semiconductor substrate 11. The material for forming each of the base layers 46 is the same as or similar to that for forming the base layer 37 of the semiconductor device 200C shown in FIG. 15B, and thus details thereof are omitted for the sake of brevity.

Each of the insulators 47 is disposed on a corresponding one of the base layers 46 opposite to the semiconductor substrate 11. The material for forming each of the insulators 47 is the same as or similar to that for forming the insulator layer 38 of the semiconductor device 200C shown in FIGS. 15A and 15B, and thus details thereof are omitted for the sake of brevity.

Each of the source/drain portions 48 is disposed on a corresponding one of the insulators 47 opposite to a corresponding one of the base layers 46. Each of the source/drain portions 48 includes a plurality of seed portions 481 and an epitaxial layer 482. Each of the seed portions 481 is disposed on a side of a corresponding one of the channel features 122. The epitaxial layer 482 is disposed over the seed portions 481. The material for forming the seed portions 481 is the same as or similar to that for forming the seed portions 391 of the semiconductor device 200C shown in FIGS. 15A and 15B, and thus details thereof are omitted for the sake of brevity. The material for forming the epitaxial layer 482 is the same as or similar to that for forming the epitaxial layer 392 of the semiconductor device 200C shown in FIGS. 15A and 15B, and thus details thereof are omitted for the sake of brevity.

Each of the metal gate portions 49 include a lower metal gate part and an upper metal gate part. The lower metal gate part of each of the metal gate portions 49 surrounds corresponding ones of the channel features 122. The upper metal gate part of each of the metal gate portions 49 is disposed on an uppermost one of the corresponding ones of the channel features 122. Each of the metal gate portions 49 includes a gate dielectric layer portion 491 and a gate electrode layer portion 492. In some embodiments, the gate dielectric layer portion 491 may include, for example, but not limited to, silicon oxide, silicon nitride, silicon oxynitride, a suitable high-k material (e.g., hafnium oxide, zirconium oxide, zirconium aluminum oxide, hafnium aluminum oxide, hafnium silicon oxide, aluminum oxide, etc.), or combinations thereof. Other suitable materials for forming the gate dielectric layer portion 491 are within the contemplated scope of the present disclosure. In some embodiments, the gate electrode layer portion 492 may include, for example, but not limited to, aluminum, copper, tungsten, cobalt, ruthenium, titanium, tantalum, molybdenum, nickel, platinum, titanium nitride, tantalum nitride, or combinations thereof. Other suitable materials for forming the gate electrode layer portion 492 are within the contemplated scope of the present disclosure.

Each of the interfacial features 50 surrounds a corresponding one of the channel features 122. In some embodiments, the interfacial features 50 may include, for example, but not limited to, silicon oxide. Other suitable materials for forming the interfacial features 50 are within the contemplated scope of the present disclosure.

Each pair of the inner spacers 51 is laterally disposed at two opposite sides (in the X direction) of the lower metal gate part of a corresponding one of the metal gate portions 49. The material for forming the inner spacers 51 is the same as or similar to that for forming the inner spacers 36 of the semiconductor device 200C shown in FIG. 15B, and thus details thereof are omitted for the sake of brevity.

Each pair of the gate spacers 52 is disposed at two opposite sides (in the X direction) of the upper metal gate part of a corresponding one of the metal gate portions 49. The material for forming the gate spacers 52 is the same as or similar to that for forming the gate spacer 23 of the semiconductor device 200B shown in FIG. 9B, and thus details thereof are omitted for the sake of brevity.

Each of the contact etch stop portions 53 is disposed on a corresponding one of the source/drain portions 48 and between corresponding two adjacent ones of the gate spacers 52. The material for forming the contact etch stop portions 53 is the same as or similar to that for forming the contact etch stop portions 24 of the semiconductor device 200B shown in FIG. 9B, and thus details thereof are omitted for the sake of brevity.

Each of the ILD portions 54 is covered by a corresponding one of the contact etch stop portions 53. The material for forming the ILD portions 54 is the same as or similar to that for forming the ILD portions 25 of the semiconductor device 200B shown in FIG. 9B, and thus details thereof are omitted for the sake of brevity.

As shown in FIG. 20B, the liner 55 is disposed between corresponding ones of the metal gate portions 49. The isolation layer portion 56 is covered by the liner 55. In some embodiments, the isolation layer portion 56 has a width (in the Y direction) ranging from about 10 nm to about 40 nm. In some embodiments, the isolation layer portion 56 has a thickness (in the Z direction) ranging from about 80 nm to about 150 nm.

Referring to FIG. 21 and the example illustrated in FIGS. 22A to 22C, the method 100D begins at step S31, where a base semiconductor structure 1d is formed. FIG. 22B illustrates a cross-sectional view taken along line U-U of FIG. 22A. FIG. 22C illustrates a cross-sectional view taken along line V-V of FIG. 22A. The base semiconductor structure 1d includes the semiconductor substrate 11, the isolation layer portions 18, the base layers 46, the insulators 47, the source/drain portions 48, a plurality of metal gates 49′, the interfacial features 50, the inner spacers 51, the gate spacers 52, the contact etch stop portions 53, the ILD portions 54, a mask layer 57′, a mask layer 58′, and a mask layer 59′.

Each of the metal gates 49′ includes a gate dielectric layer 491′ and a gate electrode layer 492′, where the gate electrode layer 492′ is surrounded by the gate dielectric layer 491′.

The mask layer 57′ is disposed on the gate electrode layer 492′, the gate spacers 52, the contact etch stop portions 53, and the ILD portions 54. In some embodiments, the mask layer 57′ includes or is made of silicon nitride, silicon carbonitride, or a combination thereof. Other suitable materials for forming the mask layer 57′ are within the contemplated scope of the present disclosure.

The mask layer 58′ is disposed on the mask layer 57′ opposite to the semiconductor substrate 11. In some embodiments, the mask layer 58′ includes or is made of silicon. Other suitable materials for forming the mask layer 58′ are within the contemplated scope of the present disclosure.

The mask layer 59′ is disposed on the mask layer 58′ opposite to the mask layer 57′. In some embodiments, the mask layer 59′ includes or is made of silicon nitride, silicon carbonitride, or a combination thereof. Other suitable materials for forming the mask layer 59′ are within the contemplated scope of the present disclosure. In some embodiments, the mask layer 59′ and the mask layer 57′ may be made of a same material or different materials.

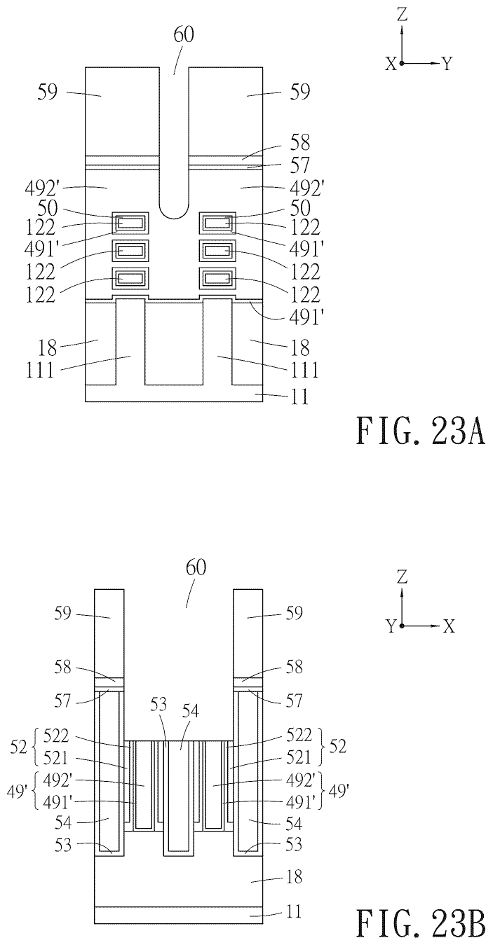

Referring to FIG. 21 and the example illustrated in FIGS. 23A and 23B, the method 100D then proceeds to step S32, where an anisotropic etching process is performed on the structures shown in FIGS. 22A to 22C, so as to form a trench 60. FIGS. 23A and 23B each illustrates a structure obtained after step S32, and the structures shown in FIGS. 23A and 23B are respectively similar to those shown in FIGS. 22B and 22C, except for inclusion of the trench 60. The trench 60 extends through the mask layer 59′, the mask layer 58′ and the mask layer 57′, and into the gate electrode layer 492′. After this step, the mask layer 59′ is formed into a plurality of mask layer portions 59, the mask layer 58′ is formed into a plurality of mask layer portions 58, the mask layer 57′ is formed into a plurality of mask layer portions 57, and each of corresponding ones of the metal gates 49′, corresponding ones of the gate spacers 52, a corresponding one of the contact etch stop portions 53, and a corresponding one of the ILD portions 54 is preliminarily etched.

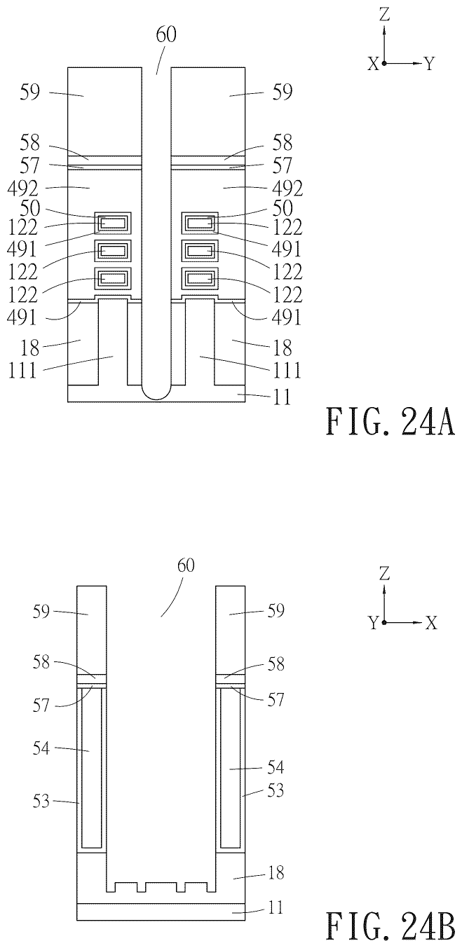

Referring to FIG. 21 and the example illustrated in FIGS. 24A and 24B, the method 100D then proceeds to step S33, where another anisotropic etching process is performed on the structure shown in each of FIGS. 23A and 23B, so as to deepen the trench 60. FIGS. 24A and 24B each illustrates a structure obtained after step S33, and the structures shown in FIGS. 24A and 24B are respectively similar to those shown in FIGS. 23A and 23B. After this step, each of the corresponding ones of the metal gates 49′, the corresponding ones of the gate spacers 52, the corresponding one of the contact etch stop portions 53, the corresponding one of the ILD portions 54 is further etched, so that the trench 60 may extend through a corresponding one of the isolation layer portions 18 and into the semiconductor substrate 11.

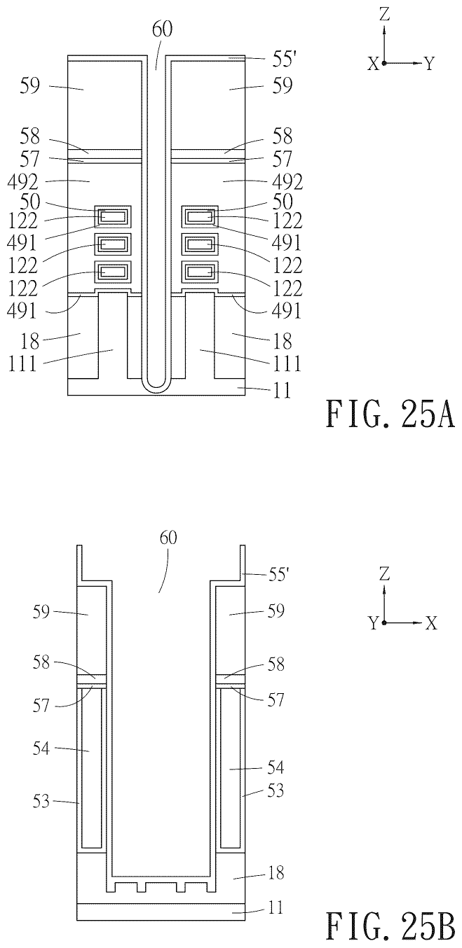

Referring to FIG. 21 and the example illustrated in FIGS. 25A and 25B, the method 100D then proceeds to step S34, where a liner layer 55′ is formed on the structures shown in FIGS. 24A and 24B. FIGS. 25A and 25B each illustrates a structure obtained after step S34, and the structures shown in FIGS. 25A and 25B are respectively similar to those shown in FIGS. 24A and 24B, except for inclusion of the liner layer 55′. The material and process for forming the liner layer 55′ may be the same as or similar to those for forming the liner layer 17′ of the structure shown in FIGS. 5A to 5C, and thus details thereof are omitted for the sake of brevity.

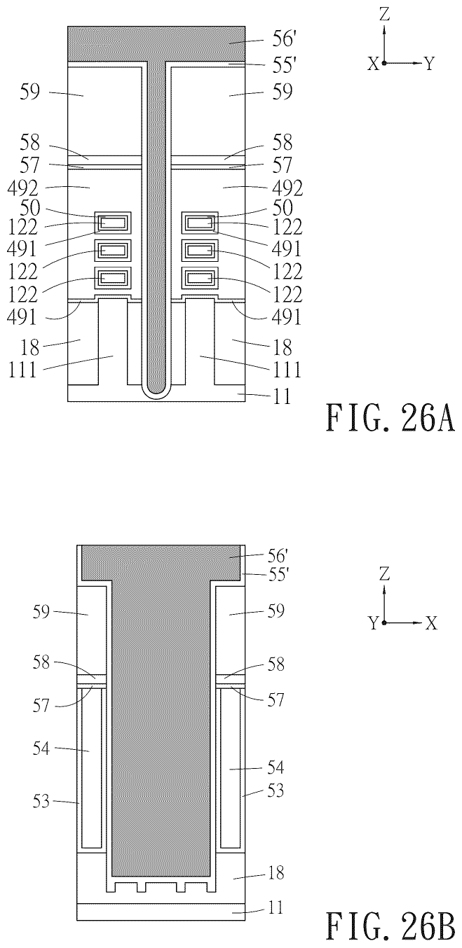

Referring to FIG. 21 and the example illustrated in FIGS. 26A and 26B, the method 100D then proceeds to step S35, where an isolation layer 56′ is formed on the structure shown in FIGS. 25A and 25B. FIGS. 26A and 26B each illustrates a structure obtained after step S35, and the structures shown in FIGS. 26A and 26B are respectively similar to those shown in FIGS. 25A and 25B, except for inclusion of the isolation layer 56′. Step S35 (i.e., formation of the isolation layer 56′) includes sub-steps (i) and (ii). Sub-step (i) of step S35 is performed by a suitable deposition process. The material and processes for performing the deposition process of sub-step (i) of step S35 are the same as or similar to those for performing the deposition process of sub-step (i) of step S05 (for forming the isolation layer 18′) in the method 100A, and thus details thereof are omitted for the sake of brevity. After the deposition process of sub-step (i) of step S35, a plurality of defects (e.g., voids or seams) (not shown) may be formed in the isolation layer 56′.

Sub-step (ii) of step S35 is performed by a cyclic ion implantation process. The material and processes for performing the cyclic ion implantation process of sub-step (ii) of step S35 are the same as or similar to those for performing the cyclic ion implantation process of sub-step (ii) of step S05 (for forming the isolation layer 18′) in the method 100A, and thus details thereof are omitted for the sake of brevity. After sub-step (ii) of step S35, the defects in the isolation layer 56′ can be eliminated.

Referring to FIG. 21 and the example illustrated in FIGS. 20A to 20C, the method 100D then proceeds to step S36, where a suitable planarization process is performed to remove an excess portion of the liner layer 55′, an excess portion of the isolation layer 56′, the mask layer portions 57, the mask layer portions 58, and the mask layer portions 59, so as to obtain the liner 55 and the isolation layer portion 56. In some embodiments, the planarization process may be a CMP or other suitable planarization processes. After this step, the semiconductor device 200D is obtained.

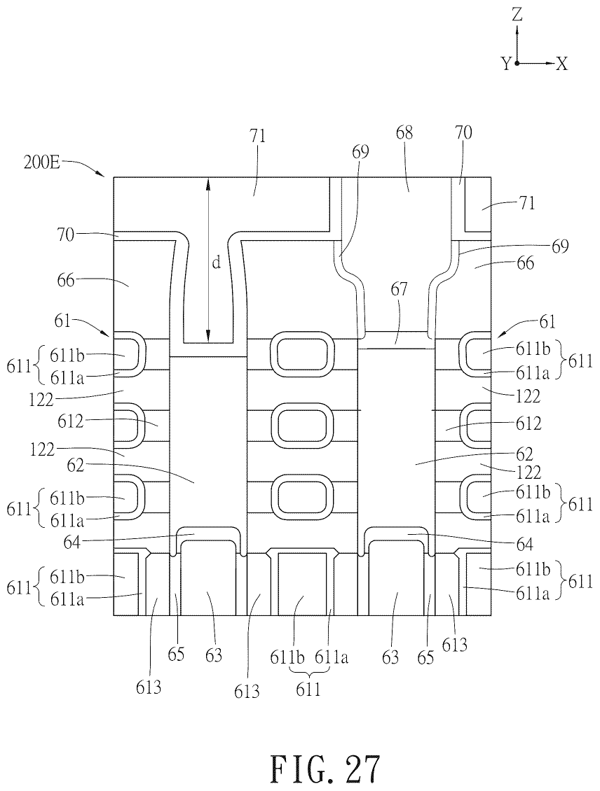

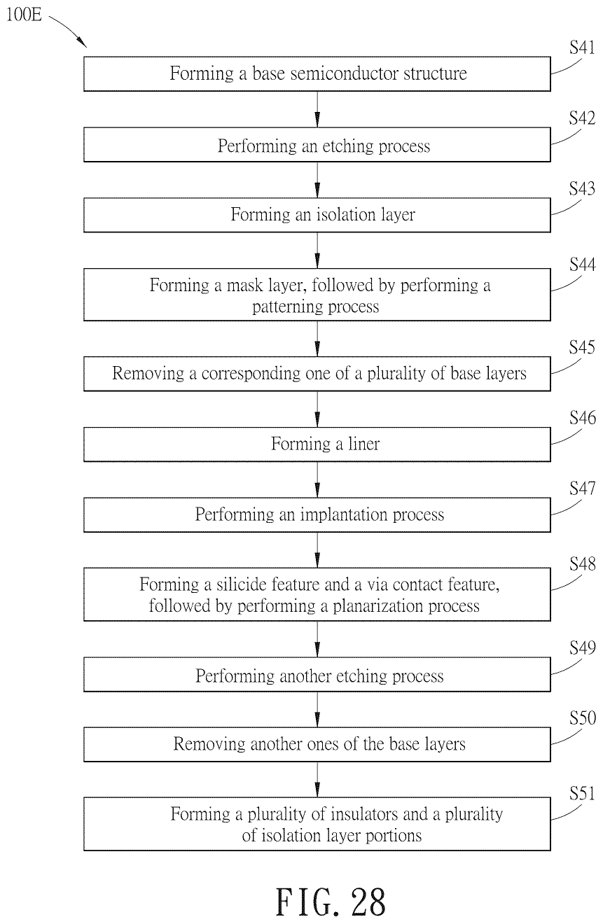

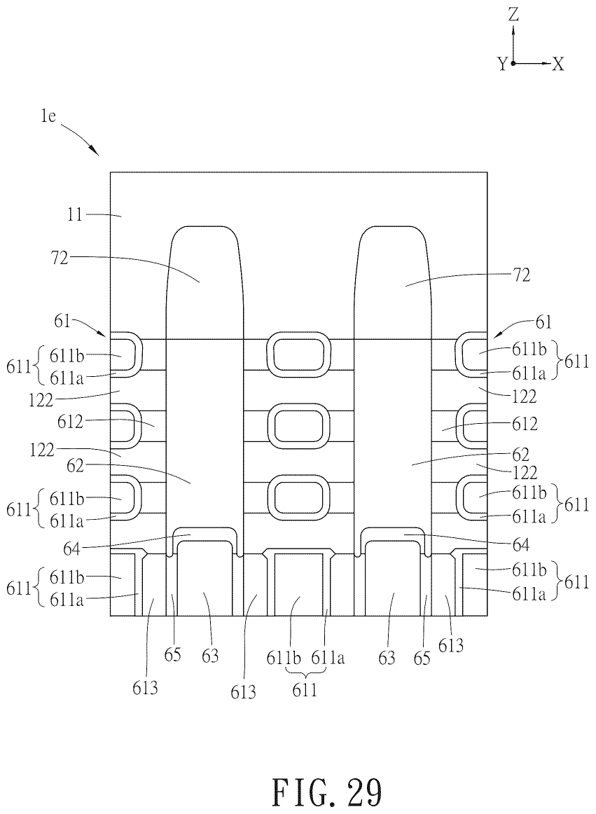

FIG. 27 illustrates a semiconductor device 200E in accordance with some embodiments. FIG. 28 is a flow diagram illustrating a method 100E for manufacturing the semiconductor device 200E in accordance with some embodiments. FIGS. 29 to 38 illustrate schematic views of some intermediate stages of the method 100E. Some portions of the semiconductor device 200E may be omitted in FIGS. 29 to 38 for the sake of brevity. Additional steps can be provided before, after or during the method 100E, and some of the steps described herein may be replaced by other steps or be eliminated. In some embodiments, the semiconductor device 200E may be formed from the semiconductor device 200D shown in FIGS. 20A to 20C.

As shown in FIG. 27, the semiconductor device 200E includes a plurality of semiconductor structures 61, a plurality of source/drain portions 62, a plurality of conductive features 63, a plurality of silicide features 64, a plurality of contact etch stop portions 65, a plurality of isolation segments 66, a silicide feature 67, a via contact feature 68, a liner segment 69, a plurality of insulators 70, and a plurality of isolation layer portions 71.

Each of the semiconductor structures 61 includes the channel features 122, a metal gate 611, a plurality of inner spacers 612, and a pair of gate spacers 613.

The metal gate 611 is disposed to surround the channel features 122. The structure of the metal gate 611 is the same as or similar to that of the metal gate portions 49 of the semiconductor device 200D shown in FIGS. 20A to 20C. The metal gate 611 includes a gate dielectric layer portion 611a and a gate electrode layer portion 611b. The material for forming the gate dielectric layer portion 611a of the metal gate 611 is the same as or similar to that for forming the gate dielectric layer portion 491 of each of the metal gate portions 49 of the semiconductor device 200D shown in FIGS. 20A to 20C, and thus details thereof are omitted for the sake of brevity. The material for forming the gate electrode layer portion 611b of the metal gate 611 is the same as or similar to that for forming the gate electrode layer portion 492 of each of the metal gate portions 49 of the semiconductor device 200D shown in FIGS. 20A to 20C, and thus details thereof are omitted for the sake of brevity.

Each pair of the inner spacers 612 is laterally disposed at two opposite sides (in the X direction) of the metal gate 611. The material for forming the inner spacers 612 is the same as or similar to that for forming the inner spacers 36 of the semiconductor device 200C shown in FIG. 15B.

The pair of the gate spacers 613 is laterally disposed at two opposite sides of a portion of the metal gate 611. The material for forming the gate spacers 613 is the same as or similar to that for forming the gate spacers 23 of the semiconductor device 200B shown in FIGS. 9A and 9B.

Each of the source/drain portions 62 is disposed between corresponding two adjacent ones of the semiconductor structures 61. The structure and material of each of the source/drain portions 62 are the same as or similar to those of the source/drain portion 39 shown in FIGS. 15A and 15B.

Each of the conductive features 63 is disposed on a corresponding one of the source/drain portions 62, and between corresponding two adjacent ones of the semiconductor structures 61. In some embodiments, each of the conductive features 63 may include, for example, but not limited to, aluminum, copper, tungsten, cobalt, ruthenium, titanium, tantalum, molybdenum, nickel, platinum, or combinations thereof. Other suitable materials for forming the conductive features 63 are within the contemplated scope of the present disclosure.

Each of the silicide features 64 is disposed between a corresponding one of the source/drain portions 62 and a corresponding one of the conductive features 63. In some embodiments, each of the silicide features 64 may include, for example, but not limited to, titanium silicide. Other suitable materials for forming the silicide features 64 are within the contemplated scope of the present disclosure.

Each pair of the contact etch stop portions 65 is laterally disposed at two opposite sides (in the X direction) of a corresponding one of the conductive features 63. The material for forming the contact etch stop portions 65 is the same as or similar to that for forming the contact etch stop portions 24 of the semiconductor device 200B shown in FIGS. 9A and 9B, and thus details thereof are omitted for the sake of brevity.

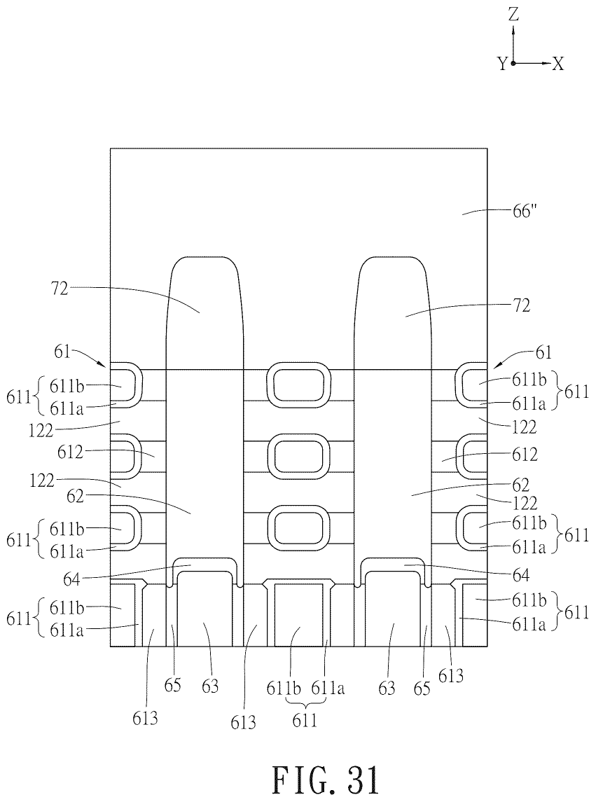

The isolation segments 66 are disposed on the semiconductor structures 61, respectively. The isolation segments 66 are formed from an isolation layer 66″ (with reference to FIG. 31).

The silicide feature 67 is disposed on a corresponding one of the source/drain portions 62 opposite to a corresponding one of the conductive features 63.

The via contact feature 68 is disposed on the silicide feature 67 opposite to a corresponding one of the source/drain portions 62.

The liner segment 69 is disposed on the silicide feature 67 and laterally covers a lower portion of the via contact feature 68.

Each of the insulators 70 is disposed on corresponding ones of the isolation segments 66, a corresponding one of the source/drain portions 62, and laterally covers an upper portion of the via contact feature 68.

The isolation layer portions 71 are disposed on the insulators 70, respectively.

Referring to FIG. 28 and the example illustrated in FIG. 29, the method 100E begins at step S41, where a base semiconductor structure 1e is formed. The base semiconductor structure 1e includes the semiconductor substrate 11, the semiconductor structures 61, the source/drain portions 62, the conductive features 63, the silicide features 64, the contact etch stop portions 65, and a plurality of base layers 72.

Each of the base layers 72 is disposed in the semiconductor substrate 11 and in contact with a corresponding one of the source/drain portions 62. In some embodiments, the base layers 72 includes or are made of silicon germanium. Other suitable materials for forming the base layers 72 are within the contemplated scope of the present disclosure.

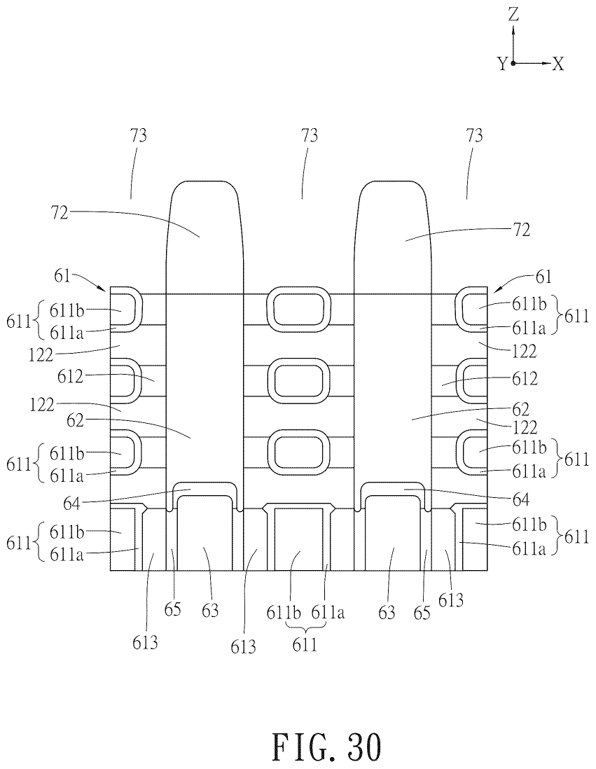

Referring to FIG. 28 and the example illustrated in FIG. 30, the method 100E then proceeds to step S42, where an etching process is performed to remove the semiconductor substrate 11. In some embodiments, the semiconductor substrate 11 may be removed by a suitable etching process, for example, but not limited to, a dry etching process, a wet etching process, or a combination thereof. Other suitable etching processes are within the contemplated scope of the present disclosure. After this step, a plurality of trenches 73 are formed.

Referring to FIG. 28 and the example illustrated in FIG. 31, the method 100E then proceeds to step S43, where the isolation layer 66″ is formed on the structure shown in FIG. 30, so that the isolation layer 66″ fully fills the trenches 73. In some embodiments, the isolation layer 66″ includes or is made of, for example, but not limited to, silicon nitride. Step S43 (i.e., formation of the isolation layer 66″) includes sub-steps (i) and (ii).

In sub-step (i) of step S43, a suitable deposition process is performed. The material and processes for performing the deposition process of sub-step (i) of step S43 are the same as or similar to those for performing the deposition process of sub-step (i) of step S05 (for forming the isolation layer 18′) in the method 100A, and thus details thereof are omitted for the sake of brevity. After the deposition process of sub-step (i) of step S43, a plurality of defects (e.g., voids or seams) (not shown) may be formed in the isolation layer 66″.

In sub-step (ii) of step S43, a cyclic ion implantation process is performed. The material and processes for performing the cyclic ion implantation process of sub-step (ii) of step S43 are the same as or similar to those for performing the cyclic ion implantation process of sub-step (ii) of step S05 (for forming the isolation layer 18′) in the method 100A, and thus details thereof are omitted for the sake of brevity. After sub-step (ii) of step S43, the defects in the isolation layer 66″ can be eliminated.

In some embodiments, the nearest distance between two adjacent ones of the base layers 72 may range from about 10 nm to about 40 nm. In some embodiments, a portion of the isolation layer 66″ filled in each of the trenches 73 formed between two adjacent ones of the base layers 72 (see FIG. 30) has a thickness ranging from about 15 nm to about 50 nm. In other words, each of the base layers 72 has a thickness in the Z direction, which ranges from about 15 nm to about 50 nm.

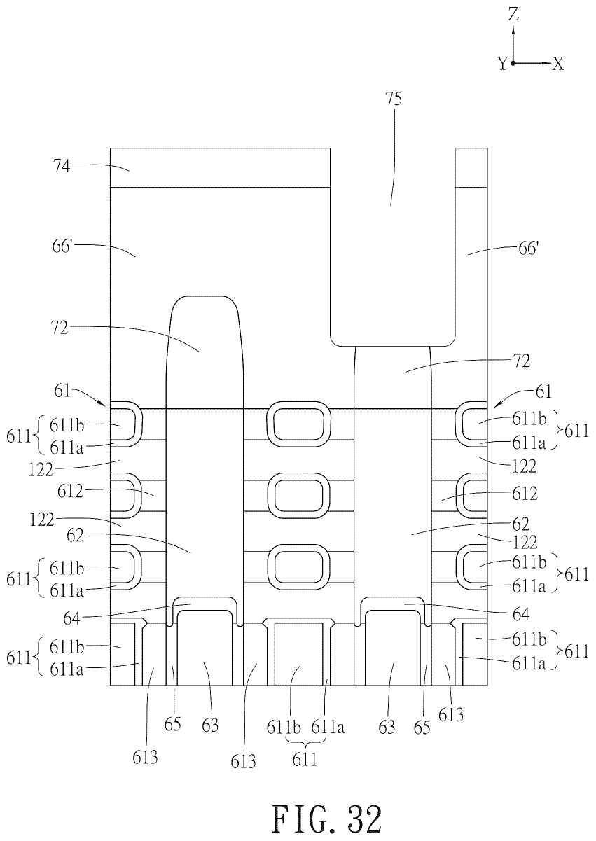

Referring to FIG. 28 and the example illustrated in FIG. 32, the method 100E then proceeds to step S44, where a mask layer 74 is formed on the structure shown in FIG. 31, followed by performing a patterning process to form a trench 75. The trench 75 extends through the mask layer 74 and the isolation layer 66″, and terminates at a corresponding one of the base layers 72. In some embodiments, the mask layer 74 includes or is made of an oxide-based material, for example, but not limited to, silicon oxide. Other suitable materials for forming the mask layer 74 are within the contemplated scope of the present disclosure. In some embodiments, the mask layer 74 may be formed by a suitable deposition process, for example, but not limited to, CVD, ALD, or physical vapor deposition (PVD). Other suitable deposition processes for forming the mask layer 74 are within the contemplated scope of the present disclosure. In some embodiments, the patterning process may be a photolithography process (including an etching process). In some embodiments, a portion of the corresponding one of the base layers 72 may be removed in this step. After this step, the isolation layer 66″ is formed into a plurality of isolation layer portions 66′.

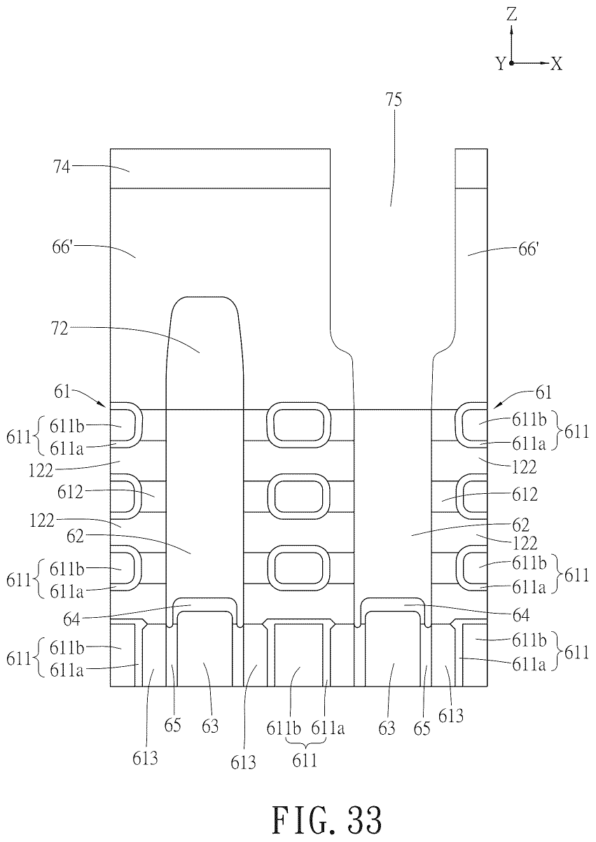

Referring to FIG. 28 and the example illustrated in FIG. 33, the method 100E then proceeds to step S45, where the corresponding one of the base layers 72 is fully removed. In step S45, removal of the corresponding one of the base layers 72 may be performed by a suitable etching process, for example, but not limited to, a dry etching process, a wet etching process, or a combination thereof. Other suitable etching processes are within the contemplated scope of the present disclosure. After this step, a depth of the trench 75 increases, and an upper surface of a corresponding one of the source/drain portions 62 is exposed.

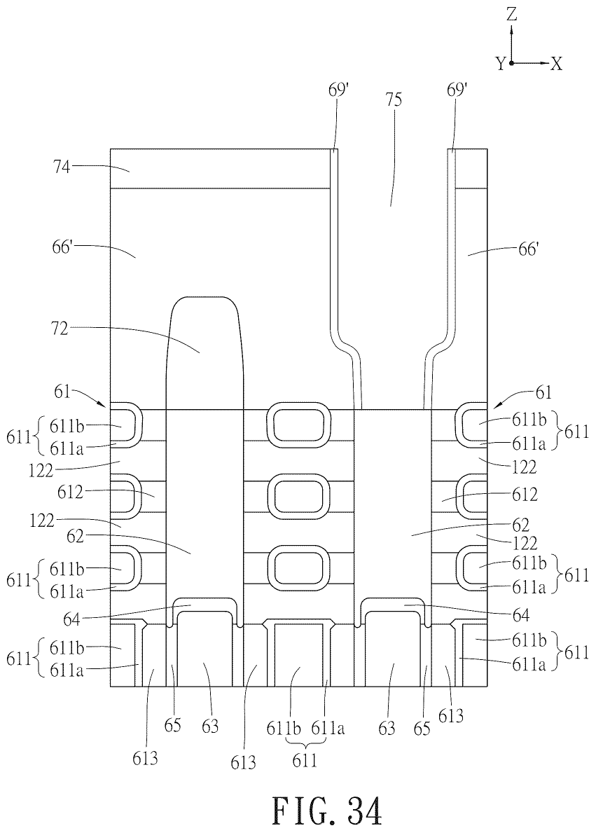

Referring to FIG. 28 and the example illustrated in FIG. 34, the method 100E then proceeds to step S46, where a liner 69′ is formed in the trench 75. The liner 69′ may be formed by forming a liner layer (not shown) on the structure shown in FIG. 33, followed by removing horizontal portions of the liner layer on the mask layer 74 and the corresponding one of the source/drain portions 62. In some embodiments, the liner layer for forming the liner 69′ includes or is made of, for example, but not limited to, silicon nitride. Other suitable materials for forming the liner layer are within the contemplated scope of the present disclosure. In some embodiments, the horizontal portions of the liner layer may be removed by a suitable etching process, for example, but not limited to, an anisotropic etching process. Other suitable etching processes are within the contemplated scope of the present disclosure.

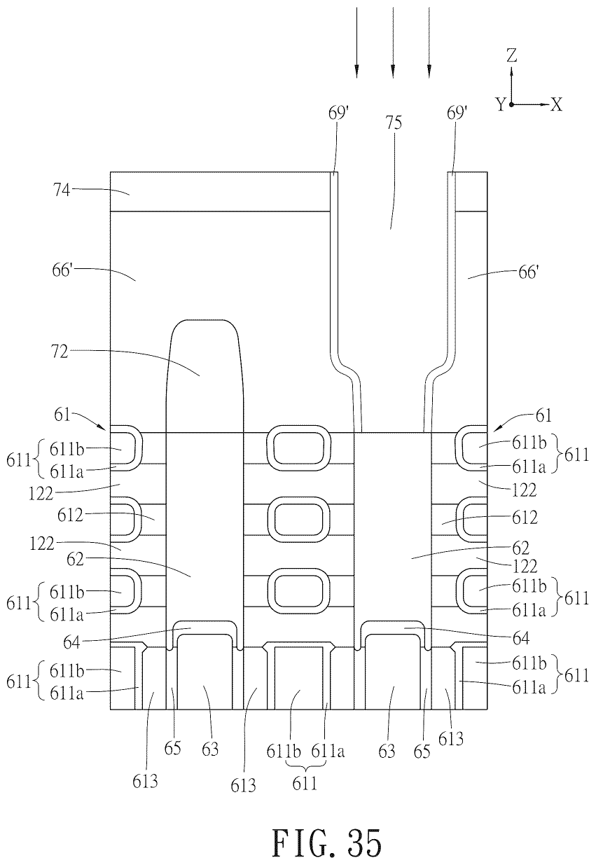

Referring to FIG. 28 and the example illustrated in FIG. 35, the method 100E then proceeds to step S47, where an implantation process is performed on the structure shown in FIG. 34. In this step, a p-type dopant (for example, but not limited to, boron, aluminum, or gallium) is introduced into the corresponding one of the source/drain portions 62, so that the corresponding one of the source/drain portions 62 has a p-type conductivity.

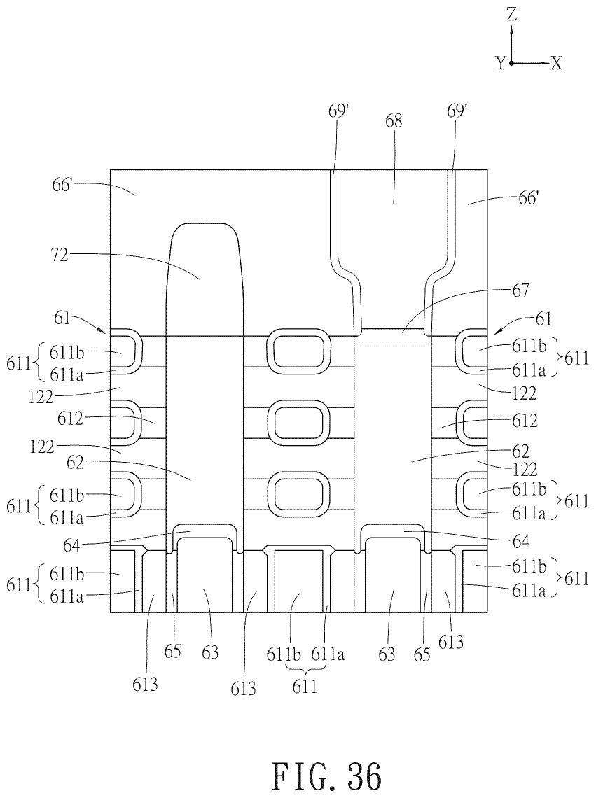

Referring to FIG. 28 and the example illustrated in FIG. 36, the method 100E then proceeds to step S48, where the silicide feature 67 and the via contact feature 68 are sequentially formed, followed by performing a planarization process. Step S48 includes sub-steps (i) to (iii).

In sub-step (i) of step S48, the silicide feature 67 is selectively formed on the corresponding one of the source/drain portions 62 and in the trench 75. The material for forming the silicide feature 67 is the same as or similar to that for forming the silicide features 64, and thus details thereof are omitted for the sake of brevity.

In sub-step (ii) of step S48, a via contact layer (not shown) for forming the via contact feature 68 is formed on a structure obtained after sub-step (i) so that the via contact layer fills the trench 75. In some embodiments, the via contact layer may include, for example, but not limited to, tungsten, ruthenium, copper, molybdenum, or combinations thereof. Other suitable materials for forming the via contact layer are within the contemplated scope of the present disclosure. In some embodiments, the via contact layer may be formed by a suitable deposition process, for example, but not limited to, CVD or ALD. Other suitable processes for forming the via contact layer are within the contemplated scope of the present disclosure.

In sub-step (iii) of step S48, the planarization process (e.g., CMP, etc.) is performed to remove a remaining portion of the mask layer 74, an excess portion of each of the isolation layer portions 66′, an excess portion of the liner 69′, and an excess portion of the via contact layer. After this sub-step, the via contact layer is formed into the via contact feature 68.

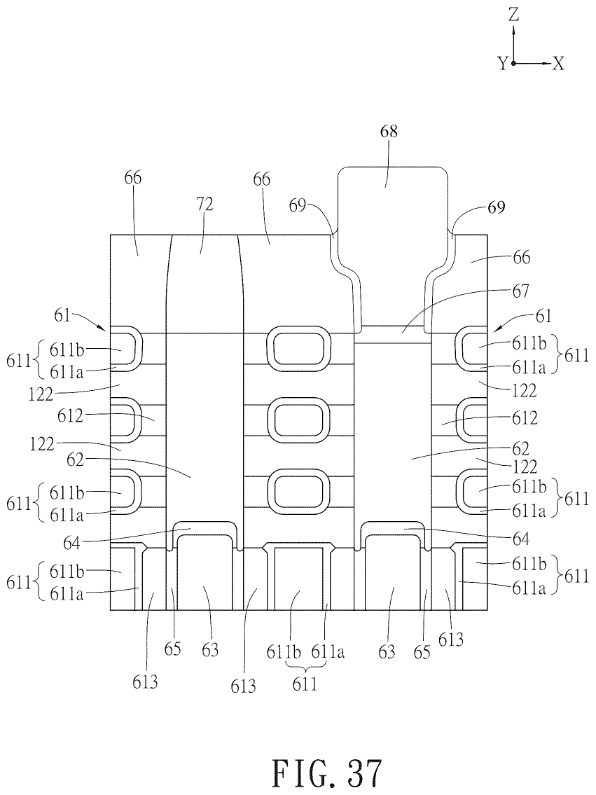

Referring to FIG. 28 and the example illustrated in FIG. 37, the method 100E then proceeds to step S49, where a part of each of the isolation layer portions 66′ and a part of the liner 69′ are removed. Step S49 is performed by a suitable etching process, for example, but not limited to, a dry etching process, a wet etching process, or a combination thereof. Other suitable etching processes are within the contemplated scope of the present disclosure. After this step, the isolation layer portions 66′ are formed into the isolation segments 66, and the liner 69′ is formed into the liner segment 69.

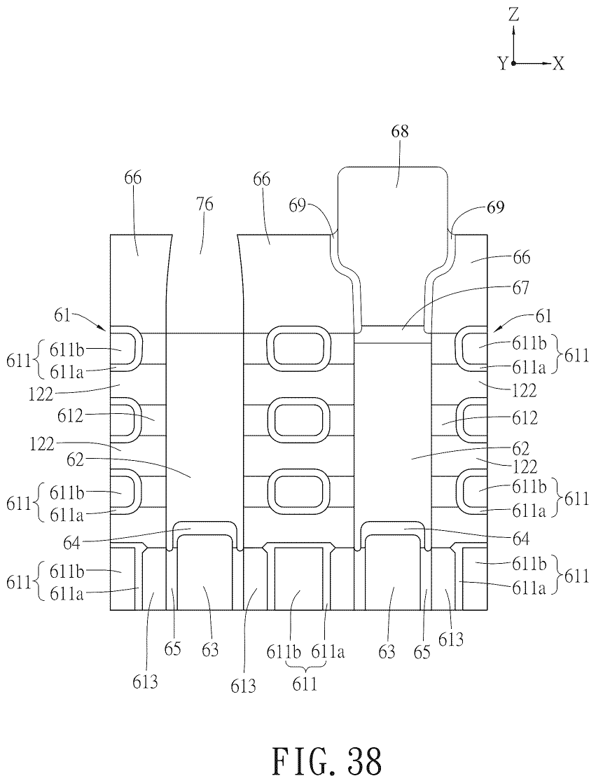

Referring to FIG. 28 and the example illustrated in FIG. 38, the method 100E then proceeds to step S50, where another ones of the base layers 72 are removed. Step S50 is performed by a suitable etching process, for example, but not limited to, a dry etching process, a wet etching process, or a combination thereof. Other suitable etching processes are within the contemplated scope of the present disclosure. After this step, a plurality of trenches 76 are formed. One of the trenches 76 is shown in FIG. 38.

Referring to FIG. 28 and the example illustrated in FIG. 27, the method 100E then proceeds to step S51, where an insulator layer (not shown) for forming the insulators 70 and an isolation layer (not shown) for forming the isolation layer portions 71 are sequentially formed on the structure shown in FIG. 38, followed by performing a planarization process. Step S51 includes sub-steps (i) to (iv).

In sub-step (i) of step S51, the insulator layer is formed on the structure shown in FIG. 38 and in the trenches 76. In some embodiments, the insulator layer includes or is made of silicon nitride. Other suitable materials for forming the insulator layer are within the contemplated scope of the present disclosure. In some embodiments, the insulator layer is formed by a suitable deposition process, for example, but not limited to, ALD. Other suitable deposition processes for forming the insulator layer are within the contemplated scope of the present disclosure.

In sub-step (ii) of step S51, a suitable deposition process is performed on the structure obtained after sub-step (i). The material and processes for performing the deposition process of sub-step (ii) of step S51 are the same as or similar to those for performing the deposition process of sub-step (i) of step S05 (for forming the isolation layer 18′) in the method 100A, and thus details thereof are omitted for the sake of brevity. After the deposition process of sub-step (ii) of step S51, a layer structure (for forming the isolation layer) is formed on the structure obtained after sub-step (i) so that the layer structure fills the trench 76. In some embodiments, a plurality of defects (e.g., voids or seams) may be formed in the layer structure.

In sub-step (iii) of step S51, a cyclic ion implantation process is performed on the structure obtained after sub-step (ii). The material and processes for performing the cyclic ion implantation process of sub-step (iii) of step S51 are the same as or similar to those for performing the cyclic ion implantation process of sub-step (ii) of step S05 (for forming the isolation layer 18′) in the method 100A, and thus details thereof are omitted for the sake of brevity. After sub-step (iii) of step S51, the isolation layer is obtained and the defects in the isolation layer can be eliminated.

In sub-step (iv) of step S51, the planarization process (e.g., CMP, etc.) is performed to remove an excess portion of the isolation layer, so as to obtain the isolation layer portions 71.

After step S51, the semiconductor device 200E is obtained. In some embodiments, the nearest horizontal distance (in the X direction) between two adjacent ones of the isolation layer portions 71 ranges from about 5 nm to about 20 nm. In some embodiments, the greatest thickness (d) of each of the isolation layer portions 71 ranges from about 10 nm to about 300 nm.

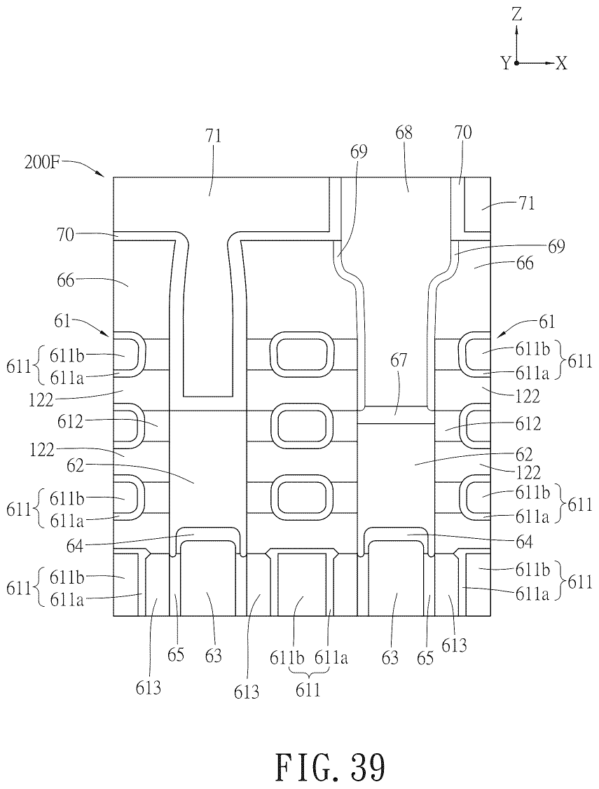

FIG. 39 illustrates a semiconductor device 200F in accordance with some embodiments. The structure of the semiconductor device 200F is generally similar to the structure of the semiconductor device 200E, except that in the semiconductor device 200F, an upper surface of each of the source/drain portions 62 is located at a level lower than that of each of uppermost ones of the channel features 122. A method for manufacturing the semiconductor device 200F may be similar to the method 100E for manufacturing the semiconductor device 200E.

In a semiconductor device of this disclosure, an isolation layer (e.g., made of silicon nitride, silicon oxide, or silicon oxynitride) is formed in a trench by a cyclic ion implantation process which may include a silicon ion implantation sub-process and at least one of a nitrogen ion implantation sub-process and an oxygen ion implantation sub-process. By performing the cyclic ion implantation process, the isolation layer may fully fill the trench without formation of defects (e.g., voids or seams) in the isolation layer. In addition, the isolation layer can be formed by a deposition process (e.g., ALD), followed by performing the cyclic ion implantation process.

In accordance with some embodiments of the present disclosure, a method for manufacturing a semiconductor device includes: forming a base semiconductor structure on a substrate; patterning the base semiconductor structure to form a trench that is recessed into the base semiconductor structure along a vertical direction normal to the base semiconductor structure; and performing a cyclic ion implantation process to form an isolation layer portion that fully fills the trench.

In accordance with some embodiments of the present disclosure, the cyclic ion implantation process includes at least one cycle of a directional ion implantation process, and ions produced in the directional ion implantation process are implanted into the trench along the vertical direction.

In accordance with some embodiments of the present disclosure, the isolation layer portion includes silicon nitride, and the directional ion implantation process includes a first directional ion implantation sub-process performed using a silicon-containing precursor, and a second directional ion implantation sub-process performed using a nitrogen-containing precursor.

In accordance with some embodiments of the present disclosure, the isolation layer portion includes silicon oxide, and the directional ion implantation process includes a first directional ion implantation sub-process performed using a silicon-containing precursor, and a second directional ion implantation sub-process performed using an oxygen-containing precursor.

In accordance with some embodiments of the present disclosure, the isolation layer portion includes silicon oxynitride, and the directional ion implantation process includes a first directional ion implantation sub-process performed using a silicon-containing precursor, a second directional ion implantation sub-process performed using an oxygen-containing precursor, and a third directional ion implantation sub-process performed using a nitrogen-containing precursor.

In accordance with some embodiments of the present disclosure, the directional ion implantation process is performed at an implant energy ranging from about 0.5 keV to about 10 keV.

In accordance with some embodiments of the present disclosure, the directional ion implantation process is performed at an implant pressure that is greater than about 1×10⁻⁵ Torr.

In accordance with some embodiments of the present disclosure, a method for manufacturing a semiconductor device includes: forming a base semiconductor structure on a substrate; patterning the base semiconductor structure to form a trench that is recessed into the base semiconductor structure along a vertical direction normal to the base semiconductor structure; performing a deposition process to form an isolation layer that fills the trench and that is formed with a seam; and subjecting the isolation layer to a cyclic ion implantation process so that the isolation layer fully fills the seam.

In accordance with some embodiments of the present disclosure, the deposition process is an atomic layer deposition process or a chemical vapor deposition process.

In accordance with some embodiments of the present disclosure, a precursor used in the deposition process includes silyl halide represented by a formula of Si(R₁)ₓ(R₂)₄₋ₓ. Each R₁ is independently hydrogen, methyl, ethyl, or propyl, each R₂ is independently fluoro, chloro, bromo, or iodo, and x is an integer ranging from 1 to 3.

In accordance with some embodiments of the present disclosure, the isolation layer includes silicon nitride, and a reaction gas used to react with the precursor in the deposition process includes a nitrogen-containing gas including nitrogen gas, ammonia gas, hydrazine gas, or combinations thereof.

In accordance with some embodiments of the present disclosure, the isolation layer includes silicon oxide, and a reaction gas used to react with the precursor in the deposition process includes an oxygen-containing gas including oxygen gas, ozone gas, or a combination thereof.

In accordance with some embodiments of the present disclosure, the isolation layer includes silicon oxynitride, and a reaction gas used to react with the precursor in the deposition process includes a combination of a nitrogen-containing gas and an oxygen-containing gas. The nitrogen-containing gas includes nitrogen gas, ammonia gas, hydrazine gas, or combinations thereof. The oxygen-containing gas includes oxygen gas, ozone gas, or a combination thereof.

In accordance with some embodiments of the present disclosure, a method for manufacturing a semiconductor device includes: forming a base semiconductor structure on a substrate; patterning the base semiconductor structure to form a trench that is recessed into the base semiconductor structure along a vertical direction normal to the base semiconductor structure; forming a liner in the trench; and performing a cyclic ion implantation process to form an isolation layer portion that fully fills the trench and that is surrounded by the liner.

In accordance with some embodiments of the present disclosure, each of the liner and the isolation layer portion independently includes silicon nitride, silicon oxide, silicon oxynitride, or combinations thereof.

In accordance with some embodiments of the present disclosure, the liner and the isolation layer portion are made of different materials.

In accordance with some embodiments of the present disclosure, the cyclic ion implantation process includes at least one cycle of a directional ion implantation process, and ions produced in the directional ion implantation process are implanted into the trench along the vertical direction.

In accordance with some embodiments of the present disclosure, the isolation layer portion includes silicon nitride, and the directional ion implantation process includes a first directional ion implantation sub-process and a second directional ion implantation sub-process. The first directional ion implantation sub-process is performed using a silicon-containing precursor including silyl halide represented by a formula of Si(R₁)ₓ(R₂)₄₋ₓ, wherein each R₁ is independently hydrogen, methyl, ethyl, or propyl, each R₂ is independently fluoro, chloro, bromo, or iodo, and x is an integer ranging from 1 to 3. The second directional ion implantation sub-process is performed using a nitrogen-containing precursor including nitrogen gas, ammonia gas, hydrazine gas, or combinations thereof.

In accordance with some embodiments of the present disclosure, the isolation layer portion includes silicon oxide, and the directional ion implantation process includes a first directional ion implantation sub-process, and a second directional ion implantation sub-process. The first directional ion implantation sub-process is performed using a silicon-containing precursor including silyl halide represented by a formula of Si(R₁)ₓ(R₂)₄₋ₓ, wherein each R₁ is independently hydrogen, methyl, ethyl, or propyl, each R₂ is independently fluoro, chloro, bromo, or iodo, and x is an integer ranging from 1 to 3. The second directional ion implantation sub-process is performed using an oxygen-containing precursor including oxygen gas, ozone gas, or a combination thereof.

In accordance with some embodiments of the present disclosure, the isolation layer portion includes silicon oxynitride, and the directional ion implantation process includes a first directional ion implantation sub-process, a second directional ion implantation sub-process, and a third directional ion implantation sub-process. The first directional ion implantation sub-process is performed using a silicon-containing precursor including silyl halide represented by a formula of Si(R₁)ₓ(R₂)₄₋ₓ, wherein each R₁ is independently hydrogen, methyl, ethyl, or propyl, each R₂ is independently fluoro, chloro, bromo, or iodo, and x is an integer ranging from 1 to 3. The second directional ion implantation sub-process is performed using an oxygen-containing precursor including oxygen gas, ozone gas, or a combination thereof. The third directional ion implantation sub-process is performed using a nitrogen-containing precursor including nitrogen gas, ammonia gas, hydrazine gas, or combinations thereof.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a base semiconductor structure on a substrate;
patterning the base semiconductor structure to form a trench that is recessed into the base semiconductor structure along a vertical direction normal to the base semiconductor structure; and
performing a cyclic ion implantation process to form an isolation layer portion that fully fills the trench.

2. The method as claimed in claim 1, wherein the cyclic ion implantation process includes at least one cycle of a directional ion implantation process, and ions produced in the directional ion implantation process are implanted into the trench along the vertical direction.

3. The method as claimed in claim 2, wherein the isolation layer portion includes silicon nitride, and the directional ion implantation process includes:
a first directional ion implantation sub-process performed using a silicon-containing precursor; and
a second directional ion implantation sub-process performed using a nitrogen-containing precursor.

4. The method as claimed in claim 2, wherein the isolation layer portion includes silicon oxide, and the directional ion implantation process includes:
a first directional ion implantation sub-process performed using a silicon-containing precursor; and
a second directional ion implantation sub-process performed using an oxygen-containing precursor.

5. The method as claimed in claim 2, wherein the isolation layer portion includes silicon oxynitride, and the directional ion implantation process includes:
a first directional ion implantation sub-process performed using a silicon-containing precursor;
a second directional ion implantation sub-process performed using an oxygen-containing precursor; and
a third directional ion implantation sub-process performed using a nitrogen-containing precursor.

6. The method as claimed in claim 2, wherein the directional ion implantation process is performed at an implant energy ranging from 0.5 keV to 10 keV.

7. The method as claimed in claim 2, wherein the directional ion implantation process is performed at an implant pressure that is greater than 1×10⁻⁵ Torr.

8. A method for manufacturing a semiconductor device, comprising:
forming a base semiconductor structure on a substrate;
patterning the base semiconductor structure to form a trench that is recessed into the base semiconductor structure along a vertical direction normal to the base semiconductor structure;
performing a deposition process to form an isolation layer that fills the trench and that is formed with a seam; and
subjecting the isolation layer to a cyclic ion implantation process so that the isolation layer fully fills the seam.

9. The method as claimed in claim 8, wherein the deposition process is an atomic layer deposition process or a chemical vapor deposition process.

10. The method as claimed in claim 9, wherein a precursor used in the deposition process includes silyl halide represented by a formula of Si(R₁)ₓ(R₂)₄₋ₓ, wherein each R₁ is independently hydrogen, methyl, ethyl, or propyl; each R₂ is independently fluoro, chloro, bromo, or iodo; and x is an integer ranging from 1 to 3.

11. The method as claimed in claim 10, wherein the isolation layer includes silicon nitride, and a reaction gas used to react with the precursor in the deposition process includes a nitrogen-containing gas including nitrogen gas, ammonia gas, hydrazine gas, or combinations thereof.

12. The method as claimed in claim 10, wherein the isolation layer includes silicon oxide, and a reaction gas used to react with the precursor in the deposition process includes an oxygen-containing gas including oxygen gas, ozone gas, or a combination thereof.

13. The method as claimed in claim 10, wherein the isolation layer includes silicon oxynitride, and a reaction gas used to react with the precursor in the deposition process includes a combination of a nitrogen-containing gas and an oxygen-containing gas, the nitrogen-containing gas including nitrogen gas, ammonia gas, hydrazine gas, or combinations thereof, the oxygen-containing gas including oxygen gas, ozone gas, or a combination thereof.

14. A method for manufacturing a semiconductor device, comprising:
forming a base semiconductor structure on a substrate;
patterning the base semiconductor structure to form a trench that is recessed into the base semiconductor structure along a vertical direction normal to the base semiconductor structure;
forming a liner in the trench; and
performing a cyclic ion implantation process to form an isolation layer portion that fully fills the trench and that is surrounded by the liner.

15. The method as claimed in claim 14, wherein each of the liner and the isolation layer portion independently includes silicon nitride, silicon oxide, silicon oxynitride, or combinations thereof.

16. The method as claimed in claim 15, wherein the liner and the isolation layer portion are made of different materials.

17. The method as claimed in claim 15, wherein the cyclic ion implantation process includes at least one cycle of a directional ion implantation process, and ions produced in the directional ion implantation process are implanted into the trench along the vertical direction.

18. The method as claimed in claim 17, wherein the isolation layer portion includes silicon nitride, and the directional ion implantation process includes:
a first directional ion implantation sub-process performed using a silicon-containing precursor including silyl halide represented by a formula of Si(R₁)ₓ(R₂)₄₋ₓ, wherein each R₁ is independently hydrogen, methyl, ethyl, or propyl, each R₂ is independently fluoro, chloro, bromo, or iodo, and x is an integer ranging from 1 to 3; and
a second directional ion implantation sub-process performed using a nitrogen-containing precursor including nitrogen gas, ammonia gas, hydrazine gas, or combinations thereof.

19. The method as claimed in claim 17, wherein the isolation layer portion includes silicon oxide, and the directional ion implantation process includes:
a first directional ion implantation sub-process performed using a silicon-containing precursor including silyl halide represented by a formula of Si(R₁)ₓ(R₂)₄₋ₓ, wherein each R₁ is independently hydrogen, methyl, ethyl, or propyl, each R₂ is independently fluoro, chloro, bromo, or iodo, and x is an integer ranging from 1 to 3; and
a second directional ion implantation sub-process performed using an oxygen-containing precursor including oxygen gas, ozone gas, or a combination thereof.

20. The method as claimed in claim 17, wherein the isolation layer portion includes silicon oxynitride, and the directional ion implantation process includes:
a first directional ion implantation sub-process performed using a silicon-containing precursor including silyl halide represented by a formula of Si(R₁)ₓ(R₂)₄₋ₓ, wherein each R₁ is independently hydrogen, methyl, ethyl, or propyl, each R₂ is independently fluoro, chloro, bromo, or iodo, and x is an integer ranging from 1 to 3;
a second directional ion implantation sub-process performed using an oxygen-containing precursor including oxygen gas, ozone gas, or a combination thereof; and
a third directional ion implantation sub-process performed using a nitrogen-containing precursor including nitrogen gas, ammonia gas, hydrazine gas, or combinations thereof.
